(19) United States
(12) Patent Application Publication
(10) Pub. No.: US 2023/0095786 A1
(43) Pub. Date: Mar. 30, 2023

(54) LIGHT EMITTING MATERIAL, DELAYED PHOSPHOR, ORGANIC LIGHT EMITTING DIODE, SCREEN, DISPLAY AND METHOD FOR PRODUCING DISPLAY

(71) Applicants: KYUSHU UNIVERSITY, NATIONAL UNIVERSITY CORPORATION, Fukuoka-shi, Fukuoka (JP); KYULUX, INC., Fukuoka-shi, Fukuoka (JP)

(72) Inventors: Hajime NAKANOTANI, Fukuoka-shi, Fukuoka (JP); Chihaya ADACHI, Fukuoka-shi, Fukuoka (JP); Hayato KAKIZOE, Fukuoka-shi, Fukuoka (JP); Ayataka ENDO, Fukuoka-shi, Fukuoka (JP)

(21) Appl. No.: 17/758,541

(22) PCT Filed: Jan. 6, 2021
(86) PCT No.: PCT/JP2021/000208

§ 371 Date: Jul. 8, 2022

(30) Foreign Application Priority Data
Jan. 10, 2020 (JP) 2020-003246

(51) Int. Cl. H01L 51/50; H01L 51/56; H01L 51/00; C09K 11/06

(52) U.S. Cl. CPC H01L 51/5024; H01L 51/56; H01L 51/0072; H01L 51/0067; C09K 11/06; H01L 2251/552; C09K 2211/1018

(57) ABSTRACT

A light emitting material containing an adjustment compound N in addition to a donor compound D and an acceptor compound A that form an exciplex and satisfying HOMO(D)>HOMO(N)>HOMO(A), LUMO(D)>LUMO(N)+0.1 eV and LUMO(N)>LUMO(A) has improved luminous efficiency or emission lifetime.

### TECHNICAL FIELD

The present invention relates to a light emitting material improved in at least one of luminous efficiency and emission lifetime. The invention also relates to a delayed fluorescent material, an organic light emitting diode, a screen and a display using such a light emitting material. The invention further relates to a method for producing the display.

### BACKGROUND ART

Studies for enhancing luminous efficiency of light emitting devices are being made actively. In particular, various studies are made for attaining efficient light emission by developing novel light emitting materials. Among them, a light emitting material using an exciplex of a combination of an acceptor compound and a donor compound is now under investigation for use as a delayed fluorescent material, because there is a possibility that, by combining a suitable acceptor compound and a suitable donor compound, the energy difference ΔEst between the excited triplet energy level and the excited singlet energy level can be reduced, as compared with a light emitting material having an acceptor and a donor in the same molecule.

For example, PTL 1 proposes a delayed fluorescent material containing a mixture of an acceptor compound and a donor compound, in which the largeness and the relationship of the excited triplet energy T₁^{A} and |LUMO^{A}| of the acceptor compound, the excited triplet energy T₁^{D} and |HOMO^{D}| of the donor compound, and the excited singlet energy S₁ of the exciplex therein are defined. The literature confirms that the light emitting device using the delayed fluorescent material attained a high luminous efficiency.

### CITATION LIST

### Patent Literature

PTL 1: JP 2012-193352 A

### SUMMARY OF INVENTION

### Technical Problem

As described in PTL 1, a conventional light emitting material that forms an exciplex is provided as a mixture of a donor compound and an acceptor compound. For improving the luminous efficiency and the emission lifetime of the light emission in which the exciplex is involved, investigations for providing a novel combination of a donor compound and an acceptor compound have heretofore been made. However, for actually confirming the effect by proposing a novel combination of a donor compound and an acceptor compound, huge trial and error experiments are required. In addition, even though a hopeful combination of a donor compound and an acceptor compound could be found out as a result of such trial and error experiments, such could not be expected to be practicable, unless other various conditions of production cost, safety and environmental acceptability could be cleared. For these reasons, considerable cost and time is required for improving the emission efficiency and lifetime for practical use, in which an exciplex is involved.

Given the situation, the present inventors promoted investigations for the purpose of improving the efficiency and the lifetime of light emission in which an exciplex is involved, by a simple means.

### Solution to Problem

As a result of extensive investigations, the present inventors have found that the luminous efficiency and the emission lifetime of a light emitting material are improved by the presence of an adjustment compound which satisfies a specific energy relationship in addition to a donor compound and an acceptor compound that form an exciplex, and have reached the present invention.

The present invention includes at least the following technical matters.

[1] A light emitting material containing, in addition to a donor compound and an acceptor compound that form an exciplex, an adjustment compound that differs from the donor compound and the acceptor compound, and satisfying a relationship of the following formula (A), formula (B1) and formula (B2):

HOMO(D)>HOMO(N)>HOMO(A) Formula (A)

LUMO(D)>LUMO(N)+0.1 eV Formula(B1)

LUMO(N)>LUMO(A) Formula(B2)

wherein HOMO(D) represents an energy level of HOMO (highest occupied molecular orbital) of the donor compound, HOMO(A) represents an energy level of HOMO of the acceptor compound, HOMO(N) represents an energy level of HOMO of the adjustment compound, LUMO(D) represents an energy level of LUMO (lowest unoccupied molecular orbital) of the donor compound, LUMO(A) represents an energy level of LUMO of the acceptor compound, LUMO(N) represents an energy level of LUMO of the adjustment compound.
[2] The light emitting material according to [1], further satisfying a relationship of the following formula (C):

HOMO(D)≥HOMO(A)+0.6 eV Formula (C)

[3] The light emitting material according to [1], further satisfying a relationship of the following formula (D) and formula (E):

T1(D)<T1(N) Formula (D)

T1(A)<T1(N) Formula (E)

wherein T1(D) represents a lowest excited triplet energy level of the donor compound, T1(A) represent a lowest excited triplet energy level of the acceptor compound, and T1(N) represents a lowest excited triplet energy level of the adjustment compound.
[4] The light emitting material according to any one of[1] to [3], wherein the content of the adjustment compound is 30% by mass or more.
[5] The light emitting material according to any one of [1] to [4], wherein the emission intensity from the exciplex is at least 10 times the emission intensity from the adjustment compound.
[6] The light emitting material according to any one of [1] to [5], further containing a light emitting compound.
[7] The light emitting material according to [6], wherein the emission intensity from the light emitting compound is at least 10 times the emission intensity from the exciplex.
[8] The light emitting material according to [6], wherein the emission intensity from the light emitting compound is at least 50 times the emission intensity from the adjustment compound.
[9] A delayed fluorescent material, containing a light emitting material of any one of [1] to [8].

An organic light emitting diode (OLED), containing a light emitting material of any one of [1] to [8].

[11] An organic light emitting diode (OLED) containing an anode, a cathode, and at least one organic layer that contains a light emitting layer between the anode and the cathode, wherein:

the light emitting layer contains a light emitting material of any one of [1] to [8].

[12] An organic light emitting diode (OLED) containing an anode, a cathode, and at least one organic layer that contains a light emitting layer between the anode and the cathode, wherein:

the light emitting layer contains a light emitting material of any one of [6] to [8].

[13] A screen or a display, containing a light emitting material of any one of [1] to [8].

A method for producing an OLED display, the method including:

a step of forming a barrier layer on a base material of a mother panel,

a step of forming plural display units on the barrier layer each on a cell panel basis,

a step of forming an encapsulation layer on each display unit of the cell panel, and

a step of forming an organic film by coating on the interface portion between the cell panels, wherein:

the organic film contains a light emitting material of any one of [1] to [8].

### Advantageous Effects of Invention

According to the present invention, there can be provided a light emitting material in which an exciplex is involved and which is improved in at least one of luminous efficiency and emission lifetime. Also according to the present invention, there can be provided a delayed fluorescent material, an organic light emitting diode, a screen and a display which are improved in at least one of luminous efficiency and emission lifetime.

### BRIEF DESCRIPTION OF DRAWINGS

FIG. 1 This is a schematic cross-sectional view showing an example of a layer configuration of an organic electroluminescent device.

FIG. 2 This is a view showing an energy level of the compounds used in the light emitting layer in Example 1.

FIG. 3 This shows emission spectra of the devices of Example 1.

FIG. 4 This is a view showing an energy level of the compounds used in the light emitting layer in Example 3.

FIG. 5 This shows emission spectra of the devices of Example 4.

### DESCRIPTION OF EMBODIMENTS

The contents of the invention will be described in detail below. The constitutional elements may be described below with reference to representative embodiments and specific examples of the invention, but the invention is not limited to the embodiments and the examples. In the description herein, a numerical range expressed as “to” means a range that includes the numerical values described before and after “to” as the upper limit and the lower limit.

### [Light Emitting Material of the Invention]

### (Energy Level of Compounds Contained in Light Emitting Material)

The light emitting material of the present invention contains a donor compound that forms an exciplex, an acceptor compound that forms the exciplex, and an adjustment compound that differs from the donor compound and the acceptor compound. The donor compound, the acceptor compound and the adjustment compound contained in the light emitting material of the present invention satisfy a relationship of the following formula (A), formula (B1) and formula (B2).

HOMO(D)>HOMO(N)>HOMO(A) Formula (A)

LUMO(D)>LUMO(N)+0.1 eV Formula (B1)

LUMO(N)>LUMO(A) Formula (B2)

In the formulae (A), (B1) and (B2), HOMO(D) represents an energy level of HOMO of the donor compound, HOMO(A) represents an energy level of HOMO of the acceptor compound, HOMO(N) represents an energy level of HOMO of the adjustment compound, LUMO(D) represents an energy level of LUMO of the donor compound, LUMO(A) represents an energy level of LUMO of the acceptor compound, LUMO(N) represents an energy level of LUMO of the adjustment compound. In the present invention, the energy level is expressed as an eV unit.

The energy level of HOMO and the energy level of LUMO in the present invention can be determined by photoelectric spectroscopy in air. In the present invention, the HOMO energy level and the LUMO energy level were measured using Riken Keiki's AC-3.

HOMO(N) may be larger than HOMO(A), and may be smaller than HOMO(D). In one embodiment of the present invention, HOMO(N) is nearer to HOMO(A) than HOMO(D). In another embodiment of the invention, HOMO(N) is nearer to HOMO(D) than HOMO(A). In another embodiment of the invention, HOMO(N) falls within the following range.

$$\frac{HOMO ( D ) + HOMO ( A )}{2} \pm [ HOMO ( D ) - HOMO ( A ) ] \times 0.3$$

In another embodiment of the invention, HOMO(N) falls within the following range.

$$\frac{HOMO ( D ) + HOMO ( A )}{2} \pm [ HOMO ( D ) - HOMO ( A ) ] \times 0.2$$

LUMO(N) may be larger than LUMO(A), and smaller by more than 0.1 eV than LUMO(D). Preferably, LUMO(N) is smaller by at least 0.2 eV than LUMO(D), in one embodiment of the present invention, LUMO(N) is smaller by at least 0.3 eV than LUMO(D), and in another embodiment of the invention, LUMO(N) is smaller by at least 0.4 eV than LUMO(D). When LUMO(N) is smaller by more than 0.1 eV than LUMO(D), higher luminous efficiency can be realized. In one embodiment of the present invention, LUMO(N) is nearer to LUMO(A) than LUMO(D). In another embodiment of the invention, LUMO(N) is nearer to LUMO(D) than LUMO(A). In another embodiment of the invention, LUMO(N) falls within the following range.

$$\frac{LUMO ( D ) + LUMO ( A )}{2} \pm [ LUMO ( D ) - LUMO ( A ) ] \times 0.3$$

In another embodiment of the invention, LUMO(N) falls within the following range.

$$\frac{LUMO ( D ) + LUMO ( A )}{2} \pm [ LUMO ( D ) - LUMO ( A ) ] \times 0.2$$

In one embodiment of the present invention, HOMO(D) and HOMO(A) satisfy the following formula.

HOMO(D)≥HOMO(A)+0.6 eV Formula (C)

In another embodiment of the invention, HOMO(D) and HOMO(A) satisfy the following formula.

HOMO(D)≥HOMO(A)+0.7 eV Formula(C1)

In another embodiment of the invention, HOMO(D) and HOMO(A) satisfy the following formula.

HOMO(D)≥HOMO(A)+0.8 eV Formula (C2)

Of the donor compound, the acceptor compound and the adjustment compound contained in the light emitting material of the present invention, the lowest excited triplet energy level preferably satisfies the following formulae (D) and (E).

T1(D)<T1(N) Formula (D)

T1(A)<T1(N) Formula (E)

In the formulae (D) and (E), T1(D) represents a lowest excited triplet energy level of the donor compound, T1(A) represents a lowest excited triplet energy level of the acceptor compound, and T1(N) represents a lowest excited triplet energy level of the adjustment compound.

In one embodiment of the present invention, the lowest excited triplet energy level satisfies the following formulae.

T1(D)+0.2 eV<T1(N) Formula (D1)

T1(A)+0.2 eV<T1(N) Formula (E1)

In another embodiment of the invention, the lowest excited triplet energy level satisfies the following formulae.

T1(D)+0.4 eV<T1(N) Formula (D2)

T1(A)+0.4 eV<T1(N) Formula (E2)

The lowest excited triplet energy level T1(N) of the adjustment compound contained in the light emitting material of the present invention can be, for example, −2.4 eV or less, or can be −2.6 eV or less, or can be −2.8 eV or less, and, for example, can be −3.2 eV or more.

### (Donor Compound Contained in Light Emitting Material)

The donor compound contained in the light emitting material of the present invention is a compound to form a exciplex along with the acceptor compound therein. In the present invention, a known donor compound capable of forming an exciplex can be employed.

In one preferred embodiment of the present invention, a donor compound having the following skeleton is employed.

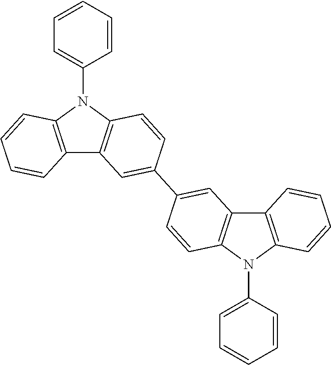 [SMILES: c1ccc(-n2c3ccccc3c3cc(-c4ccc5c(c4)c4ccccc4n5-c4ccccc4)ccc32)cc1]

The hydrogen atom of the above skeleton can be substituted with a substituent. The number thereof substituted with a substituent can be 0, or can be 1, or can be 2, or can be 3, or can be 4 or more. When substituted with 2 or more substituents, these substituents can be the same or different. Preferably, the substituent is selected from a deuterium, a substituted or unsubstituted alkyl, a substituted or unsubstituted alkoxy, a substituted or unsubstituted amino, a substituted or unsubstituted aryl, a substituted or unsubstituted aryloxy, a substituted or unsubstituted heteroaryl, a substituted or unsubstituted heteroaryloxy and a silyl.

The molecular weight of the donor compound can be selected from a range of, for example, 200 or more, 250 or more, or 300 or more, or can be selected from a range of 2000 or less, 1000 or less, or 700 or less.

Specific examples of the donor compound are shown below, but the donor compound that can be employed in the present invention is not limitatively interpreted by the following exemplary compounds.

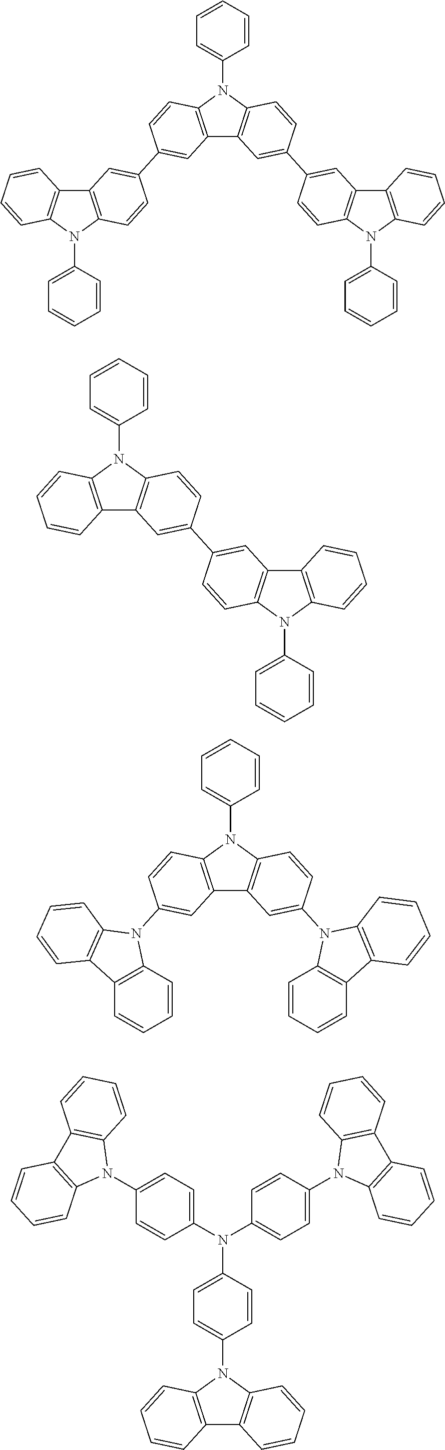

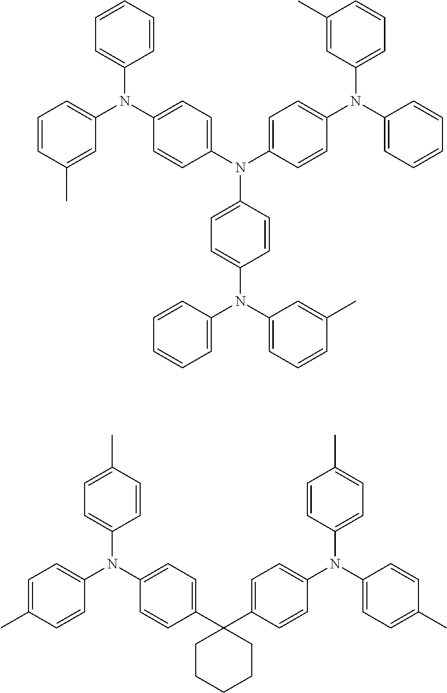

### (Acceptor Compound Contained in Light Emitting Material)

The acceptor compound contained in the light emitting material of the present invention is a compound that forms an exciplex along with the donor compound therein. In the present invention, a known acceptor compound capable of forming an exciplex can be employed.

In a preferred embodiment of the present invention, an acceptor compound having the following skeleton is employed.

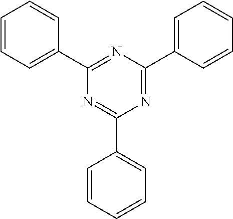 [SMILES: c1ccc(-c2nc(-c3ccccc3)nc(-c3ccccc3)n2)cc1]

The hydrogen atom of the above skeleton can be substituted with a substituent. The number thereof substituted with a substituent can be 0, or can be 1, or can be 2, or can be 3, or can be 4 or more. When substituted with 2 or more substituents, these substituents can be the same or different. Preferably, the substituent is selected from a deuterium, a substituted or unsubstituted alkyl, a substituted or unsubstituted alkoxy, a substituted or unsubstituted amino, a substituted or unsubstituted aryl, a substituted or unsubstituted aryloxy, a substituted or unsubstituted heteroaryl, a substituted or unsubstituted heteroaryloxy and a silyl.

The molecular weight of the acceptor compound can be selected from a range of, for example, 200 or more, 250 or more, or 300 or more, or can be selected from a range of 2000 or less, 1000 or less, or 700 or less.

Specific examples of the acceptor compound are shown below, but the acceptor compound that can be employed in the present invention is not limitatively interpreted by the following exemplary compounds.

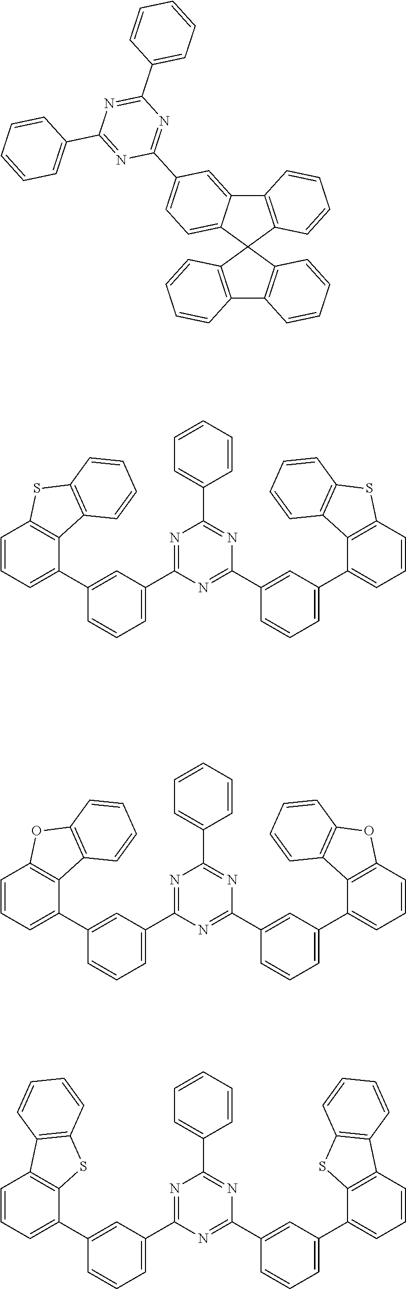 [SMILES: c1ccc(-c2nc(-c3ccccc3)nc(-c3ccc4c(c3)-c3ccccc3C43c4ccccc4-c4ccccc43)n2)cc1 ; c1ccc(-c2nc(-c3cccc(-c4cccc5sc6ccccc6c45)c3)nc(-c3cccc(-c4cccc5sc6ccccc6c45)c3)n2)cc1 ; c1ccc(-c2nc(-c3cccc(-c4cccc5oc6ccccc6c45)c3)nc(-c3cccc(-c4cccc5oc6ccccc6c45)c3)n2)cc1 ; c1ccc(-c2nc(-c3cccc(-c4cccc5c4sc4ccccc45)c3)nc(-c3cccc(-c4cccc5c4sc4ccccc45)c3)n2)cc1]

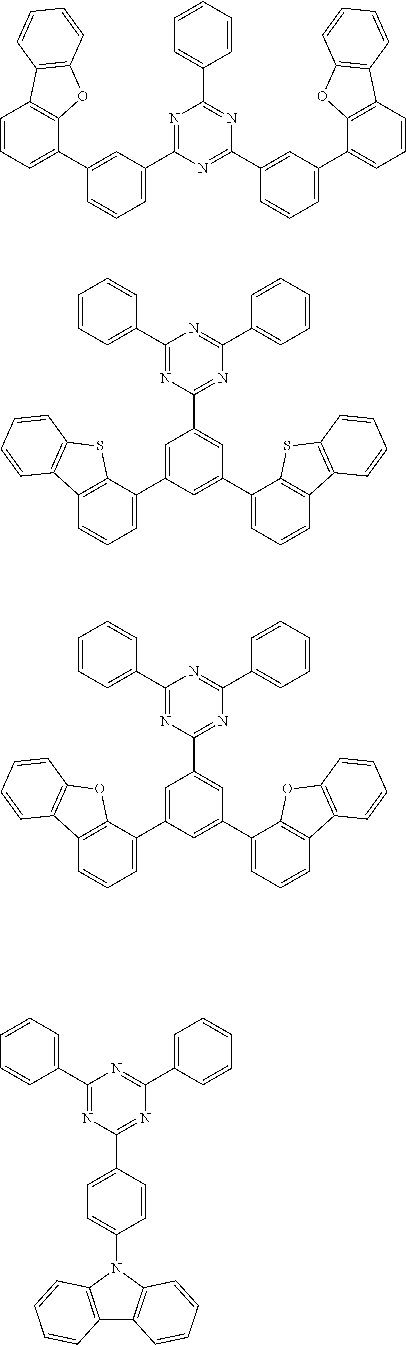 [SMILES: c1ccc(-c2nc(-c3cccc(-c4cccc5c4oc4ccccc45)c3)nc(-c3cccc(-c4cccc5c4oc4ccccc45)c3)n2)cc1 ; c1ccc(-c2nc(-c3ccccc3)nc(-c3cc(-c4cccc5c4sc4ccccc45)cc(-c4cccc5c4sc4ccccc45)c3)n2)cc1 ; c1ccc(-c2nc(-c3ccccc3)nc(-c3cc(-c4cccc5c4oc4ccccc45)cc(-c4cccc5c4oc4ccccc45)c3)n2)cc1 ; c1ccc(-c2nc(-c3ccccc3)nc(-c3ccc(-n4c5ccccc5c5ccccc54)cc3)n2)cc1]

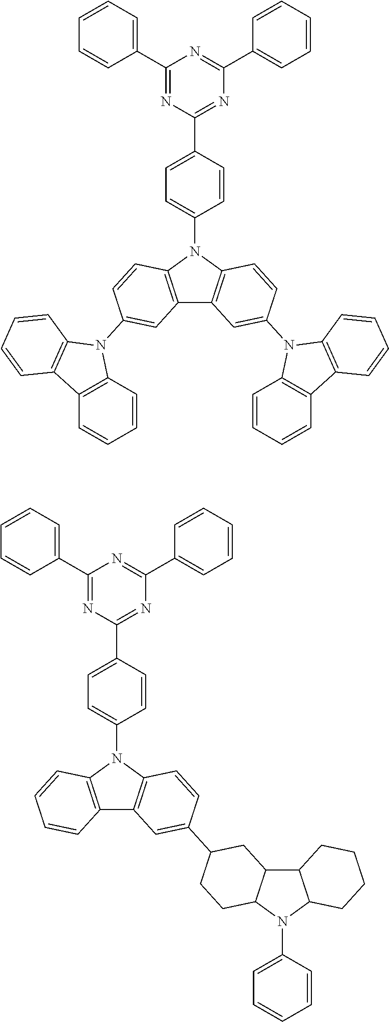 [SMILES: c1ccc(-c2nc(-c3ccccc3)nc(-c3ccc(-n4c5ccc(-n6c7ccccc7c7ccccc76)cc5c5cc(-n6c7ccccc7c7ccccc76)ccc54)cc3)n2)cc1 ; c1ccc(-c2nc(-c3ccccc3)nc(-c3ccc(-n4c5ccccc5c5cc(C6CCC7C(C6)C6CCCCC6N7c6ccccc6)ccc54)cc3)n2)cc1]

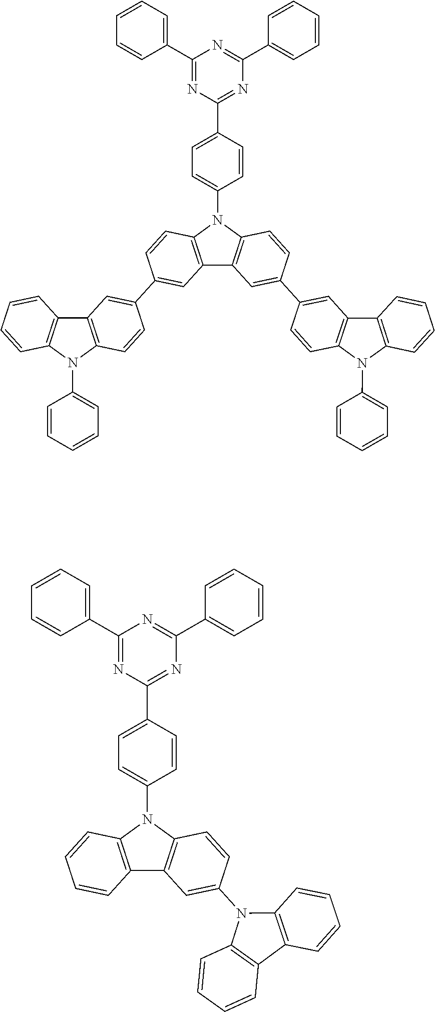 [SMILES: c1ccc(-c2nc(-c3ccccc3)nc(-c3ccc(-n4c5ccc(-c6ccc7c(c6)c6ccccc6n7-c6ccccc6)cc5c5cc(-c6ccc7c(c6)c6ccccc6n7-c6ccccc6)ccc54)cc3)n2)cc1 ; c1ccc(-c2nc(-c3ccccc3)nc(-c3ccc(-n4c5ccccc5c5cc(-n6c7ccccc7c7ccccc76)ccc54)cc3)n2)cc1]

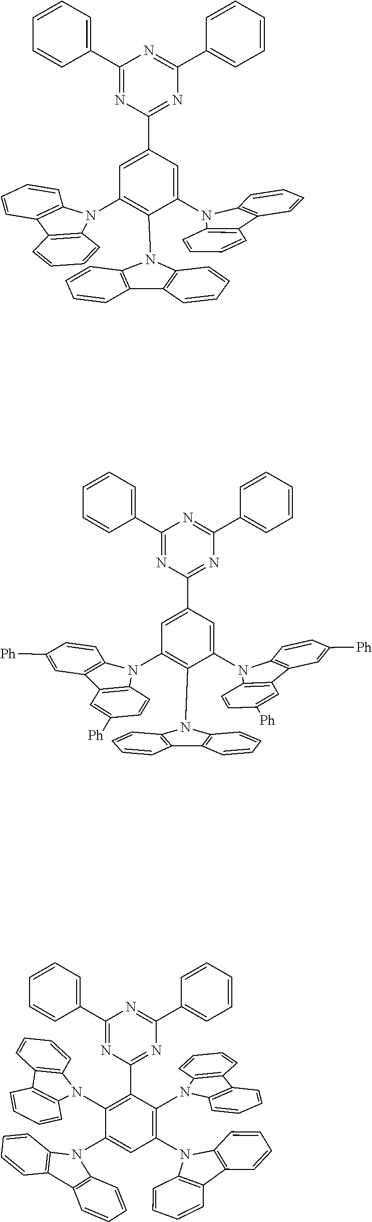 [SMILES: c1ccc(-c2nc(-c3ccccc3)nc(-c3cc(-n4c5ccccc5c5ccccc54)c(-n4c5ccccc5c5ccccc54)c(-n4c5ccccc5c5ccccc54)c3)n2)cc1 ; c1ccc(-c2ccc3c(c2)c2cc(-c4ccccc4)ccc2n3-c2cc(-c3nc(-c4ccccc4)nc(-c4ccccc4)n3)cc(-n3c4ccc(-c5ccccc5)cc4c4cc(-c5ccccc5)ccc43)c2-n2c3ccccc3c3ccccc32)cc1 ; c1ccc(-c2nc(-c3ccccc3)nc(-c3c(-n4c5ccccc5c5ccccc54)c(-n4c5ccccc5c5ccccc54)cc(-n4c5ccccc5c5ccccc54)c3-n3c4ccccc4c4ccccc43)n2)cc1]

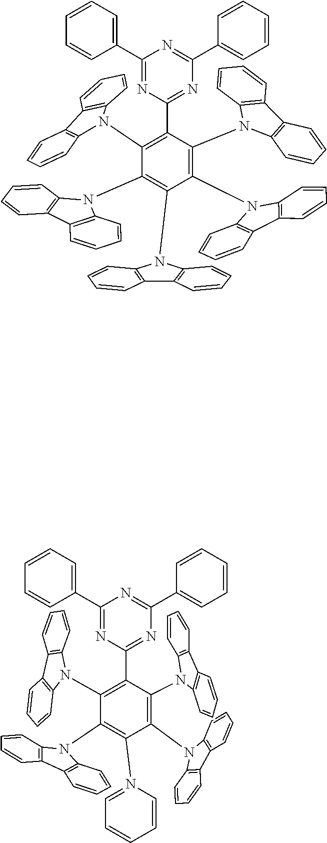

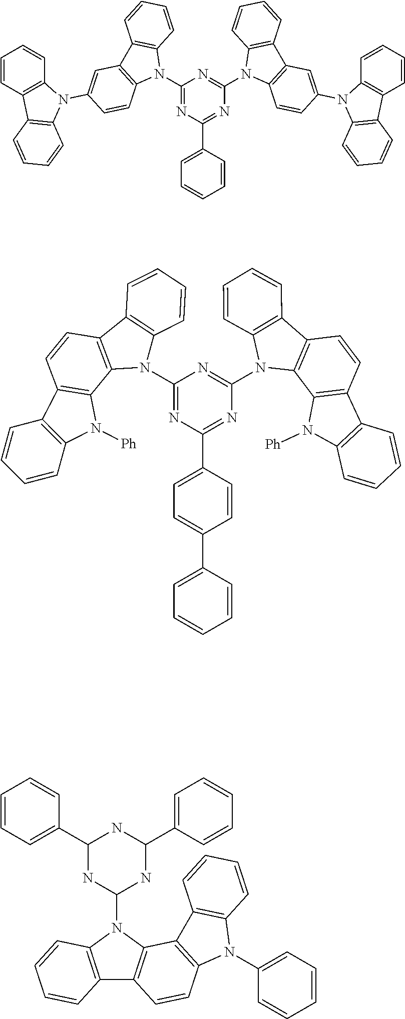 [SMILES: c1ccc(-c2nc(-n3c4ccccc4c4cc(-n5c6ccccc6c6ccccc65)ccc43)nc(-n3c4ccccc4c4cc(-n5c6ccccc6c6ccccc65)ccc43)n2)cc1 ; c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(C2NC(c3ccccc3)NC(n3c4ccccc4c4ccc5c(c6ccccc6n5-c5ccccc5)c43)N2)cc1]

In the light emitting material of the present invention, the donor compound and an acceptor compound form an exciplex. The exciplex is an associate of the acceptor compound and the donor compound, and when given excitation energy, it is converted into an excited state owing to electron transition from the donor compound to the acceptor compound. The light emitting material of the present invention can be such that the exciplex therein emits light, or when further containing a light emitting compound to be mentioned hereinunder, the light emitting compound emits light, or both the exciplex and the light emitting compound emit light. Preferably, the exciplex emits light in a visible range, and can emit light of, for example, blue, green, yellow or red. Also preferably, the exciplex radiates delayed fluorescence, but may radiate ordinary fluorescence. The difference ΔE_{ST} between the lowest excited single energy and the lowest excited triplet energy of the exciplex is preferably 0.3 eV or less, more preferably 0.2 eV or less, even more preferably 0.1 eV or less, further more preferably 0.05 eV or less, especially more preferably 0.02 eV or less.

In one embodiment of the present invention, the emission intensity from the exciplex can be controlled to fall within a range of, for example, 0.1% or more, 1% or more, 10% or more, 25% or more, 50% or more, 75% or more, 90% or more, or 99% or more, or can be 100%, based on the emission intensity from the light emitting material of 100%. Also it can be controlled to fall within a range of 95% or less, 70% or less, 40% or less, 30% or less, 10% or less, or 1% or less. In one embodiment of the present invention, the emission from any other than the exciplex and the light emitting compound can be controlled to fall within a range of 20% or less, 10% or less, 5% or less, 1% or less, 0.1% or less or 0.01% or less, and can be 0%.

### (Adjustment Compound Contained in Light Emitting Material)

The adjustment compound contained in the light emitting material of the present invention can be any one that satisfies the formula (A), the formula (B1) and the formula (B2), and the structure thereof is not limited.

In one embodiment of the present invention, the adjustment compound is a compound having a donor site and an acceptor site in the molecule. Compounds having the following structure are exemplified, in which the donor site is represented by D and the acceptor site is by A.

### D-A

### D-A-D

### D-A-D-A-D

### A-D-A

### A-D-A-D-A

### (A)m-D

### (D)n-A

In the case where two or more D's exist in the molecule, they may be the same as or different from each other, and in the case where two or more A's exists in the molecule, they may be the same as or different from each other, m represents an integer of 3 or more and not more than the maximum number substitutable with D, and n represents an integer of 3 or more and not more than the maximum number substitutable with A.

For the donor site D, a group having a negative Hammett's σp value is employable. For the acceptor site A, a group having a positive Hammett's σp value is employable. Here, “Hammett's σp value” is one propounded by L. P. Hammett, and is to quantify the influence of a substituent on the reaction rate or the equilibrium of a para-substituted benzene derivative. Specifically, this is a constant (σp value) specific to the substituent in the following expression:

log(k/k₀)=ρσp

or

log(K/K₀)=ρσp,

which is established between the substituent in a para-substituted benzene derivative and the reaction rate constant or the equilibrium constant thereof. In the above expressions, k represents a rate constant of a benzene derivative not having a substituent, k₀ represents a rate constant of a benzene derivative substituted with a substituent, K represents an equilibrium constant of a benzene derivative not having a substituent, K₀ represents an equilibrium constant of a benzene derivative substituted with a substituent, and ρ represents a reaction constant determined by the kind and the condition of reaction. Regarding the description relating to the “Hammett's σp value” in the present invention and the numerical value of each substituent, reference can be made to the description relating to the σp value in Hansch, C, et. al., Chem. Rev., 91, 165-195 (1991).

In another embodiment of the present invention, the adjustment compound is a compound having two or more donor sites and a linking group linking them in the molecule. For example, compounds having the following structure can be exemplified, in which the donor site is represented by D and the linking group is L or L′.

### D-L-D

### D-L-D-L-D

### (D)n-L′

In the case where two or more D's exist in the molecule, they may be the same as or different from each other, and in the case where two or more L's exist in the molecule, they may be the same as or different from each other. n represents an integer of 3 or more and not more than the maximum number substitutable with L′, and L′ represents an n-valent linking group.

Examples of the linking groups L and L′ include a substituted or unsubstituted arylene group, a substituted or unsubstituted alkenylene group, and a substituted or unsubstituted alkynylene group. Examples thereof also include groups formed by linking two or more groups selected from a substituted or unsubstituted arylene group, a substituted or unsubstituted alkenylene group, and a substituted or unsubstituted alkynylene group. Here, the arylene group can be selected, for example, from a range of a carbon number of 6 to 30, a carbon number of 6 to 20, a carbon number of 6 to 14, or a carbon number of 6 to 10. Specific examples thereof include a 1,4-phenylene group, a 1,3-phenylene group, a 1,2-phenylene group, a 1,8-naphthylene group, a 1,4-naphthylene group, a 1,2-naphthylene group, a 2,3-naphthylene group, a 2,6-naphthylene group, a 2,7-naphthylene group, a 9,10-anthracenylene group, a 2,3-anthracenylene group, a 2,6-anthracenylene group, a 2,7-anthracenylene group, a 1,8-anthracenylene group, and a 1,5-anthracenylene group. Here, the alkenylene group can be selected, for example, from a range of a carbon number of 2 to 20, a carbon number of 2 to 10, a carbon number of 2 to 6, or a carbon number of 2 to 4. Specific examples thereof include a group represented by —(CR¹═CR²)ₙ₁—. Here, R¹ and R² each independently represent a hydrogen atom or a substituent. Examples of the substituent include an alkyl group having 1 to 10 carbon atoms, an alkenyl group having 2 to 10 carbon atoms, an alkynyl group having 2 to 10 carbon atoms, and an aryl group having 6 to 30 carbon atoms. n1 represents an integer of 1 to 10. Here, the alkynylene group can be selected, for example, from a range of a carbon number of 2 to 20, a carbon number of 2 to 10, a carbon number of 2 to 6, or a carbon number of 2 to 4. Specific examples thereof include an ethynylene group. Examples of the substituent for the arylene group and the alkenylene group that the linking group L′ can represent include an alkyl group having 1 to 10 carbon atoms, an alkenyl group having 2 to 10 carbon atoms, an alkynyl group having 2 to 10 carbon atoms, and an aryl group having 6 to 30 carbon atoms.

The molecular weight of the adjustment compound can be selected, for example, from a range of 200 or more, 250 or more, or 300 or more, or can be selected from a range of 2000 or less, 1000 or less, or 700 or less.

Specific examples of the adjustment compound are shown below, but the adjustment compound that can be employed in the present invention is not limitatively interpreted by the following exemplary compounds.

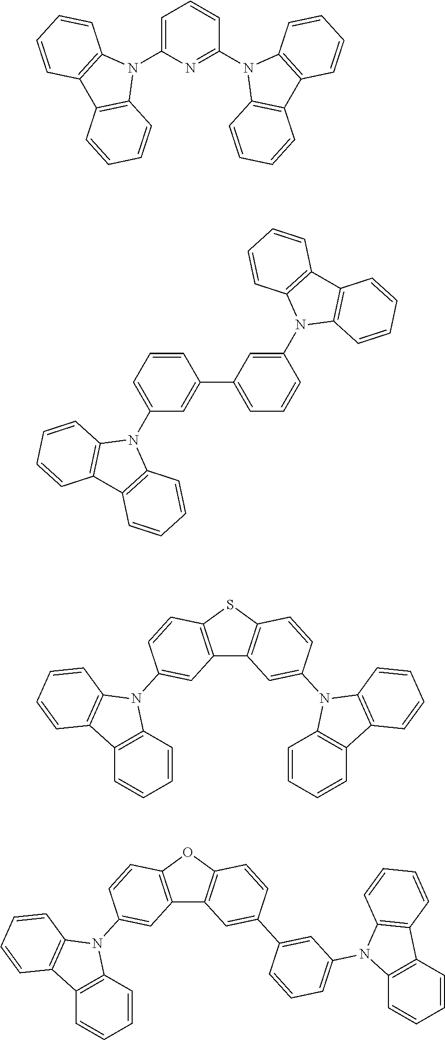 [SMILES: c1cc(-n2c3ccccc3c3ccccc32)nc(-n2c3ccccc3c3ccccc32)c1 ; c1cc(-c2cccc(-n3c4ccccc4c4ccccc43)c2)cc(-n2c3ccccc3c3ccccc32)c1 ; c1ccc2c(c1)c1ccccc1n2-c1ccc2sc3ccc(-n4c5ccccc5c5ccccc54)cc3c2c1 ; c1cc(-c2ccc3oc4ccc(-n5c6ccccc6c6ccccc65)cc4c3c2)cc(-n2c3ccccc3c3ccccc32)c1]

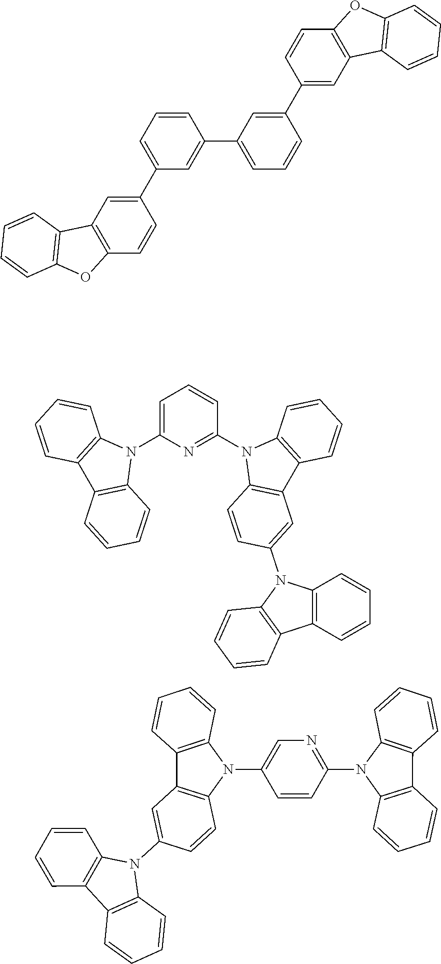

### (Light Emitting Compound)

The light emitting material of the present invention can contain a light emitting compound as a compound other than the donor compound, the acceptor compound and the adjustment compound. The light emitting compound as referred to herein is not one corresponding to the adjustment compound that satisfies the formula (A), the formula (B1) and the formula (B2).

The light emitting compound contained in the light emitting material of the present invention is preferably a compound that emits light when having received energy from the exciplex formed by the donor compound and the acceptor compound. Two or more kinds of light emitting compounds can be contained. In such a case, energy transfer can be made from one light emitting compound to the other light emitting compound, and energy transfer can be made directly from the exciplex to each of the two or more light emitting compounds.

Preferably, the light emitting compound emits light in a visible range, and can emit light of, for example, blue, green, yellow or red. Also preferably, the light emitting compound can radiate fluorescence or phosphorescence or can radiate delayed fluorescence.

When containing a light emitting compound, the light emitting material of the present invention may emit light from the light emitting compound alone, or may emit light from the light emitting compound and the others. In the latter case, the emission intensity of the light emitting compound can be the largest, or the emission intensity from the light emitting compound can be smaller than the emission intensity from the others than the light emitting compound (e.g., the exciplex formed by the donor compound and the acceptor compound). The emission intensity from the light emitting material can be controlled by controlling the kind and the content of the light emitting compound. Based on the emission intensity from the light emitting material of 100%, the emission intensity from the light emitting compound can be controlled to fall within a range of, for example, 0.1% or more, 1% or more, 10% or more, 25% or more, 50% or more, 75% or more, 90% or more or 99% or more. It can also be controlled to fall within a range of, for example, 95% or less, 70% or less, 40% or less, 30% or less, 10% or less, or 1% or less. The emission intensity from the light emitting compound can be 1.5 times or more, 2 times or more, 5 times or more, 10 times or more, or 100 times or more the emission intensity from the exciplex, or can be 0.5 times or less, 0.1 times or less, or 0.01 times or less. The emission intensity from the light emitting compound can be 3 times or more, 10 times or more, 50 times or more, or 100 times or more the emission intensity from the adjustment compound.

Examples of the light emitting compound usable in the light emitting material of the present invention are shown below, but the light emitting compound that can be employed in the present invention is not limitatively interpreted by the following compounds.

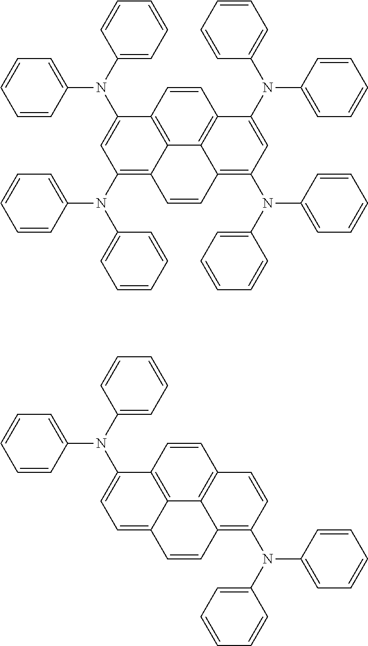 [SMILES: c1ccc(N(c2ccccc2)c2cc(N(c3ccccc3)c3ccccc3)c3ccc4c(N(c5ccccc5)c5ccccc5)cc(N(c5ccccc5)c5ccccc5)c5ccc2c3c54)cc1 ; c1ccc(N(c2ccccc2)c2ccc3ccc4c(N(c5ccccc5)c5ccccc5)ccc5ccc2c3c54)cc1]

### (Composition of Light Emitting Material)

The content of the donor compound, the acceptor compound and the adjustment compound contained in the light emitting material is not specifically limited so far as light emission is enabled. Based on the total amount of the light emitting material of 100% by mass, the content of each compound can be selected within a range of 0.01 to 99.99% by mass. Each compound can be each independently selected from a range of, for example, 0.1% by mass or more, 1% by mass or more, 5% by mass or more, 10% by mass or more, 30% by mass or more, 50% by mass or more, 70% by mass or more, or 90% by mass or more, or from a range of 80% by mass or less, 60% by mass or less, 40% by mass or less, 20% by mass or less, 10% by mass or less, 5% by mass or less, or 1% by mass or less.

In one embodiment of the present invention, the content of the adjustment compound is larger than the content of the donor compound, or is larger than the content of the acceptor compound. In one embodiment of the invention, the content of the adjustment compound is not less than the total content of the donor compound and acceptor compound.

In another embodiment of the present invention, the content of the adjustment compound is less than the total content of the donor compound and the acceptor compound. In another embodiment of the invention, the content of the adjustment compound is smaller than the content of the donor compound, or is smaller than the content of the acceptor compound.

In the light emitting material of the present invention, the content of the donor compound can be the same as the content of the acceptor compound, or the content of donor compound can be larger than that of the acceptor compound (for example, the content of the donor compound can be 2 times or more, or 4 times or more, or 10 times or more the content of the acceptor compound), or the content of the acceptor compound can be larger than that of the donor compound (for example, the content of the acceptor compound can be 2 times or more, or 4 times or more, or 10 times or more the content of the donor compound).

In the light emitting material of the present invention, the content of the donor compound can be the same as the content of the adjustment compound, or the content of donor compound can be larger than that of the adjustment compound (for example, the content of the donor compound can be 2 times or more, or 4 times or more, or 10 times or more the content of the adjustment compound), or the content of the adjustment compound can be larger than that of the donor compound (for example, the content of the adjustment compound can be 2 times or more, or 4 times or more, or 10 times or more the content of the donor compound).

In the light emitting material of the present invention, the content of the acceptor compound can be the same as the content of the adjustment compound, or the content of acceptor compound can be larger than that of the adjustment compound (for example, the content of the acceptor compound can be 2 times or more, or 4 times or more, or 10 times or more the content of the adjustment compound), or the content of the adjustment compound can be larger than that of the acceptor compound (for example, the content of the adjustment compound can be 2 times or more, or 4 times or more, or 10 times or more the content of the acceptor compound).

By increasing the content of the adjustment compound therein, the light emitting material of the present invention tends to be improved in at least one of luminous efficiency and emission lifetime. Also by increasing the content of the adjustment compound, the light emitting material of the present invention tents to have a prolonged lifetime of delayed fluorescence.

In the case where the light emitting material of the present invention contains a light emitting compound as a compound other than the donor compound, the acceptor compound and the adjustment compound, the content thereof can be selected, for example, from a range of 0.01% by mass or more, 0.1% by mass or more, 1% by mass or more, 3% by mass or more, 5% by mass or more, 10% by mass or more, or 20% by mass or more, or from a range of 30% by mass or less, 15% by mass or less, 10% by mass or less, 5% by mass or less, or 1% by mass or less.

In one embodiment of the present invention, the light emitting material of the present invention does not contain a light emitting compound, and of the emission from the light emitting material of the present invention, the emission intensity from the exciplex formed by the donor compound and the acceptor compound is the largest.

The light emitting material of the present invention can contain a compound not corresponding to any of the donor compound, the acceptor compound, the adjustment compound and the light emitting compound. The light emitting material of the present invention can be formed of the donor compound, the acceptor compound, the adjustment compound and the light emitting compound.

### Definitions

Unless otherwise defined herein, scientific and technical terms used in this application shall have the meanings that are commonly understood by those of ordinary skill in the art. Generally, nomenclature used in connection with, and techniques of, chemistry described herein, are those well-known and commonly used in the art.

The term “acyl” is art-recognized and refers to a group represented by the general formula hydrocarbylC(O)—, preferably alkylC(O)—.

The term “acylamino” is art-recognized and refers to an amino group substituted with an acyl group and may be represented, for example, by the formula hydrocarbylC(O)NH—.

The term “acyloxy” is art-recognized and refers to a group represented by the general formula hydrocarbylC(O)O—, preferably alkylC(O)O—.

The term “alkoxy” refers to an alkyl group, having an oxygen attached thereto. In some embodiments, an alkoxy has 1-20 carbon atoms. In some embodiments, an alkoxy has 1-12 carbon atoms. Representative alkoxy groups include methoxy, trifluoromethoxy, ethoxy, propoxy, tert-butoxy and the like.

The term “alkoxyalkyl” refers to an alkyl group substituted with an alkoxy group and may be represented by the general formula alkyl-O-alkyl.

The term “alkenyl”, as used herein, refers to an aliphatic group comprising at least one double bond and is intended to include both “unsubstituted alkenyls” and “substituted alkenyls”, the latter of which refers to alkenyl moieties having substituents replacing a hydrogen on one or more carbons of the alkenyl group. Typically, a straight chained or branched alkenyl group has from 1 to about 20 carbon atoms, preferably from 1 to about 12 unless otherwise defined. Such substituents may occur on one or more carbons that are included or not included in one or more double bonds. Moreover, such substituents include all those contemplated for alkyl groups, as discussed below, except where stability is prohibitive. For example, substitution of alkenyl groups by one or more alkyl, carbocyclyl, aryl, heterocyclyl, or heteroaryl groups is contemplated.

An “alkyl” group or “alkane” is a straight chained or branched non-aromatic hydrocarbon which is completely saturated. Typically, a straight chained or branched alkyl group has from 1 to about 20 carbon atoms, preferably from 1 to about 12 unless otherwise defined. In some embodiments, the alkyl group has from 1 to 8 carbon atoms, from 1 to 6 carbon atoms, from 1 to 4 carbon atoms, or from 1 to 3 carbon atoms. Examples of straight chained and branched alkyl groups include methyl, ethyl, n-propyl, iso-propyl, n-butyl, sec-butyl, tert-butyl, pentyl, hexyl, pentyl and octyl.

Moreover, the term “alkyl” as used throughout the specification, examples, and claims is intended to include both “unsubstituted alkyls” and “substituted alkyls”, the latter of which refers to alkyl moieties having substituents replacing a hydrogen on one or more substitutable carbons of the hydrocarbon backbone. Such substituents, if not otherwise specified, can include, for example, a halogen (e.g., fluoro), a hydroxyl, a carbonyl (such as a carboxyl, an alkoxycarbonyl, a formyl, or an acyl), a thiocarbonyl (such as a thioester, a thioacetate, or a thioformate), an alkoxy, a phosphoryl, a phosphate, a phosphonate, a phosphinate, an amino, an amido, an amidine, an imine, a cyano, a nitro, an azido, a sulfhydryl, an alkylthio, a sulfate, a sulfonate, a sulfamoyl, a sulfonamido, a sulfonyl, a heterocyclyl, an aralkyl, or an aromatic or heteroaromatic moiety. In preferred embodiments, the substituents on substituted alkyls are selected from C₁₋₆ alkyl, C₃₋₆ cycloalkyl, halogen, carbonyl, cyano, or hydroxyl. In more preferred embodiments, the substituents on substituted alkyls are selected from fluoro, carbonyl, cyano, or hydroxyl. It will be understood by those skilled in the art that the moieties substituted on the hydrocarbon chain can themselves be substituted, if appropriate. For instance, the substituents of a substituted alkyl may include substituted and unsubstituted forms of amino, azido, imino, amido, phosphoryl (including phosphonate and phosphinate), sulfonyl (including sulfate, sulfonamido, sulfamoyl and sulfonate), and silyl groups, as well as ethers, alkylthios, carbonyls (including ketones, aldehydes, carboxylates, and esters), —CF₃, —CN and the like. Exemplary substituted alkyls are described below. Cycloalkyls can be further substituted with alkyls, alkenyls, alkoxys, alkylthios, aminoalkyls, carbonyl-substituted alkyls. —CF₃. —CN, and the like.

The term “C_{x-y}” when used in conjunction with a chemical moiety, such as, acyl, acyloxy, alkyl, alkenyl, alkynyl, or alkoxy is meant to include groups that contain from x to y carbons in the chain. For example, the term “C_{x-y} alkyl” refers to substituted or unsubstituted saturated hydrocarbon groups, including straight-chain alkyl and branched-chain alkyl groups that contain from x to y carbons in the chain, including haloalkyl groups. Preferred haloalkyl groups include trifluoromethyl, difluoromethyl, 2,2,2-trifluoroethyl, and pentafluoroethyl. C₀ alkyl indicates a hydrogen where the group is in a terminal position, a bond if internal. The terms “C_{2-y} alkenyl” and “C_{2-y} alkynyl” refer to substituted or unsubstituted unsaturated aliphatic groups analogous in length and possible substitution to the alkyls described above, but that contain at least one double or triple bond respectively.

The term “alkylamino”, as used herein, refers to an amino group substituted with at least one alkyl group.

The term “alkylthio”, as used herein, refers to a thiol group substituted with an alkyl group and may be represented by the general formula alkylS—.

The term “arylthio”, as used herein, refers to a thiol group substituted with an alkyl group and may be represented by the general formula arylS—.

The term “alkynyl”, as used herein, refers to an aliphatic group comprising at least one triple bond and is intended to include both “unsubstituted alkynyls” and “substituted alkynyls”, the latter of which refers to alkynyl moieties having substituents replacing a hydrogen on one or more carbons of the alkynyl group. Typically, a straight chained or branched alkynyl group has from 1 to about 20 carbon atoms, preferably from 1 to about 10 unless otherwise defined. Such substituents may occur on one or more carbons that are included or not included in one or more triple bonds. Moreover, such substituents include all those contemplated for alkyl groups, as discussed above, except where stability is prohibitive. For example, substitution of alkynyl groups by one or more alkyl, carbocyclyl, aryl, heterocyclyl, or heteroaryl groups is contemplated.

The term “amide”, as used herein, refers to a group

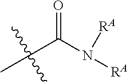

wherein each R^{A} independently represents a hydrogen or hydrocarbyl group, or two R^{A} are taken together with the N atom to which they are attached complete a heterocycle having from 4 to 8 atoms in the ring structure.

The terms “amine” and “amino” are art-recognized and refer to both unsubstituted and substituted amines and salts thereof, e.g., a moiety that can be represented by

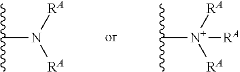

wherein each R^{A} independently represents a hydrogen or a hydrocarbyl group, or two R^{A} are taken together with the N atom to which they are attached complete a heterocycle having from 4 to 8 atoms in the ring structure.

The term “aminoalkyl”, as used herein, refers to an alkyl group substituted with an amino group.

The term “aralkyl”, as used herein, refers to an alkyl group substituted with an aryl group.

The term “aryl” as used herein include substituted or unsubstituted single-ring aromatic groups in which each atom of the ring is carbon. Preferably the ring is a 6- or 20-membered ring, more preferably a 6-membered ring. Preferably aryl having 6-40 carbon atoms, more preferably having 6-25 carbon atoms.

The term “aryl” also includes polycyclic ring systems having two or more cyclic rings in which two or more carbons are common to two adjoining rings wherein at least one of the rings is aromatic, e.g., the other cyclic rings can be cycloalkyls, cycloalkenyls, cycloalkynyls, aryls, heteroaryls, and/or heterocyclyls. Aryl groups include benzene, naphthalene, phenanthrene, phenol, aniline, and the like.

The term “carbamate” is art-recognized and refers to a group

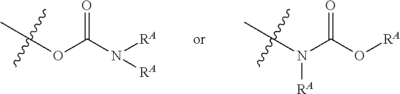

wherein each R^{A} independently represent hydrogen or a hydrocarbyl group, such as an alkyl group, or both R^{A} taken together with the intervening atom(s) complete a heterocycle having from 4 to 8 atoms in the ring structure.

The terms “carbocycle”, and “carbocyclic”, as used herein, refers to a saturated or unsaturated ring in which each atom of the ring is carbon. Preferably, a carbocylic group has from 3 to 20 carbon atoms. The term carbocycle includes both aromatic carbocycles and non-aromatic carbocycles. Non-aromatic carbocycles include both cycloalkane rings, in which all carbon atoms are saturated, and cycloalkene rings, which contain at least one double bond. “Carbocycle” includes 5-7 membered monocyclic and 8-12 membered bicyclic rings. Each ring of a bicyclic carbocycle may be selected from saturated, unsaturated and aromatic rings. Carbocycle includes bicyclic molecules in which one, two or three or more atoms are shared between the two rings. The term “fused carbocycle” refers to a bicyclic carbocycle in which each of the rings shares two adjacent atoms with the other ring. Each ring of a fused carbocycle may be selected from saturated, unsaturated and aromatic rings. In an exemplary embodiment, an aromatic ring, e.g., phenyl (Ph), may be fused to a saturated or unsaturated ring, e.g., cyclohexane, cyclopentane, or cyclohexene. Any combination of saturated, unsaturated and aromatic bicyclic rings, as valence permits, is included in the definition of carbocyclic. Exemplary “carbocycles” include cyclopentane, cyclohexane, bicyclo[2.2.1]heptane, 1,5-cyclooctadiene, 1,2,3,4-tetrahydronaphthalene, bicyclo[4.2.0]oct-3-ene, naphthalene and adamantane. Exemplary fused carbocycles include decalin, naphthalene, 1,2,3,4-tetrahydronaphthalene, bicyclo[4.2.0]octane, 4,5,6,7-tetrahydro-1H-indene and bicyclo[4.1.0]hept-3-ene. “Carbocycles” may be substituted at any one or more positions capable of bearing a hydrogen atom.

A “cycloalkyl” group is a cyclic hydrocarbon which is completely saturated. “Cycloalkyl” includes monocyclic and bicyclic rings. Preferably, a cycloalkyl group has from 3 to 20 carbon atoms. Typically, a monocyclic cycloalkyl group has from 3 to about 10 carbon atoms, more typically 3 to 8 carbon atoms unless otherwise defined. The second ring of a bicyclic cycloalkyl may be selected from saturated, unsaturated and aromatic rings. Cycloalkyl includes bicyclic molecules in which one, two or three or more atoms are shared between the two rings. The term “fused cycloalkyl” refers to a bicyclic cycloalkyl in which each of the rings shares two adjacent atoms with the other ring. The second ring of a fused bicyclic cycloalkyl may be selected from saturated, unsaturated and aromatic rings. A “cycloalkenyl” group is a cyclic hydrocarbon comprising one or more double bonds.

The term “carbocyclylalkyl,” as used herein, refers to an alkyl group substituted with a carbocycle group.

The term “carbonate,” as used herein, refers to a group —OCO₂—R^{A}, wherein R^{A} represents a hydrocarbyl group.

The term “carboxy,” as used herein, refers to a group represented by the formula —CO₂H.

The term “ester.” as used herein, refers to a group —C(O)OR^{A} wherein R^{A} represents a hydrocarbyl group.

The term “ether,” as used herein, refers to a hydrocarbyl group linked through an oxygen to another hydrocarbyl group. Accordingly, an ether substituent of a hydrocarbyl group may be hydrocarbyl-O—. Ethers may be either symmetrical or unsymmetrical. Examples of ethers include, but are not limited to, heterocycle-O-heterocycle and aryl-O-heterocycle. Ethers include “alkoxyalkyl” groups, which may be represented by the general formula alkyl-O-alkyl.

The terms “halo” and “halogen” as used herein means halogen and includes chloro, fluoro, bromo, and iodo.

The terms “hetaralkyl” and “heteroaralkyl,” as used herein, refers to an alkyl group substituted with a hetaryl group.

The term “heteroalkyl,” as used herein, refers to a saturated or unsaturated chain of carbon atoms and at least one heteroatom, wherein no two heteroatoms are adjacent. The terms “heteroaryl” and “hetaryl” include substituted or unsubstituted aromatic single ring structures, preferably 5- to 20-membered rings, more preferably 5- to 6-membered rings, whose ring structures include at least one heteroatom, preferably one to four heteroatoms, more preferably one or two heteroatoms. Preferably a heteroaryl having 2-40 carbon atoms, more preferably having 2-25 carbon atoms. The terms “heteroaryl” and “hetaryl” also include polycyclic ring systems having two or more cyclic rings in which two or more carbons are common to two adjoining rings wherein at least one of the rings is heteroaromatic, e.g., the other cyclic rings can be cycloalkyls, cycloalkenyls, cycloalkynyls, aryls, heteroaryls, and/or heterocyclyls. Heteroaryl groups include, for example, pyrrole, furan, thiophene, imidazole, oxazole, thiazole, pyrazole, pyridine, pyrazine, pyridazine, pyrimidine, and carbazole, and the like.

The term “aryloxy” refers to an aryl group, having an oxygen attached thereto. Preferably aryloxy having 6-40 carbon atoms, more preferably having 6-25 carbon atoms.

The term “heteroaryloxy” refers to an aryl group, having an oxygen attached thereto. Preferably heteroaryloxy having 3-40 carbon atoms, more preferably having 3-25 carbon atoms.

The term “heteroatom” as used herein means an atom of any element other than carbon or hydrogen. Preferred heteroatoms are nitrogen, oxygen, and sulfur.

The terms “heterocyclyl,” “heterocycle,” and “heterocyclic” refer to substituted or unsubstituted non-aromatic ring structures, preferably 3- to 20-membered rings, more preferably 3- to 7-membered rings, whose ring structures include at least one heteroatom, preferably one to four heteroatoms, more preferably one or two heteroatoms. The terms “heterocyclyl” and “heterocyclic” also include polycyclic ring systems having two or more cyclic rings in which two or more carbons are common to two adjoining rings wherein at least one of the rings is heterocyclic, e.g., the other cyclic rings can be cycloalkyls, cycloalkenyls, cycloalkynyls, aryls, heteroaryls, and/or heterocyclyls. Heterocyclyl groups include, for example, piperidine, piperazine, pyrrolidine, morpholine, lactones, lactams, and the like.

The term “heterocyclylalkyl,” as used herein, refers to an alkyl group substituted with a heterocycle group.

The term “hydrocarbyl,” as used herein, refers to a group that is bonded through a carbon atom, wherein that carbon atom does not have a ═O or ═S substituent. Hydrocarbyls may optionally include heteroatoms. Hydrocarbyl groups include, but are not limited to, alkyl, alkenyl, alkynyl, alkoxyalkyl, aminoalkyl, aralkyl, aryl, aralkyl, carbocyclyl, cycloalkyl, carbocyclylalkyl, heteroaralkyl, heteroaryl groups bonded through a carbon atom, heterocyclyl groups bonded through a carbon atom, heterocyclylalkyl, or hydroxyalkyl. Thus, groups like methyl, ethoxyethyl, 2-pyridyl, and trifluoromethyl are hydrocarbyl groups, but substituents such as acetyl (which has a ═O substituent on the linking carbon) and ethoxy (which is linked through oxygen, not carbon) are not.

The term “hydroxyalkyl,” as used herein, refers to an alkyl group substituted with a hydroxy group.

The term “lower” when used in conjunction with a chemical moiety, such as, acyl, acyloxy, alkyl, alkenyl, alkynyl, or alkoxy is meant to include groups where there are six or fewer non-hydrogen atoms in the substituent. A “lower alkyl,” for example, refers to an alkyl group that contains six or fewer carbon atoms. In some embodiments, the alkyl group has from 1 to 6 carbon atoms, from 1 to 4 carbon atoms, or from 1 to 3 carbon atoms. In certain embodiments, acyl, acyloxy, alkyl, alkenyl, alkynyl, or alkoxy substituents defined herein are respectively lower acyl, lower acyloxy, lower alkyl, lower alkenyl, lower alkynyl, or lower alkoxy, whether they appear alone or in combination with other substituents, such as in the recitations hydroxyalkyl and aralkyl (in which case, for example, the atoms within the aryl group are not counted when counting the carbon atoms in the alkyl substituent).

The terms “polycyclyl,” “polycycle”, and “polycyclic” refer to two or more rings (e.g., cycloalkyls, cycloalkenyls, cycloalkynyls, aryls, heteroaryls, and/or heterocyclyls) in which two or more atoms are common to two adjoining rings, e.g., the rings are “fused rings”. Each of the rings of the polycycle can be substituted or unsubstituted. In certain embodiments, each ring of the polycycle contains from 3 to 10 atoms in the ring, preferably from 5 to 7.

In the phrase “poly(meta-phenylene oxides),” the term “phenylene” refers inclusively to 6-membered aryl or 6-membered heteroaryl moieties. Exemplary poly(meta-phenylene oxides) are described in the first through twentieth aspects of the present disclosure.

The term “silyl” refers to a silicon moiety with three hydrocarbyl moieties attached thereto.

The term “substituted” refers to moieties having substituents replacing a hydrogen on one or more carbons of the backbone. It will be understood that “substitution” or “substituted with” includes the implicit proviso that such substitution is in accordance with permitted valence of the substituted atom and the substituent, and that the substitution results in a stable compound, e.g., which does not spontaneously undergo transformation such as by rearrangement, cyclization, elimination, etc. Moieties that may be substituted can include any appropriate substituents described herein, for example, acyl, acylamino, acyloxy, alkoxy, alkoxyalkyl, alkenyl, alkyl, alkylamino, alkylthio, arylthio, alkynyl, amide, amino, aminoalkyl, aralkyl, carbamate, carbocyclyl, cycloalkyl, carbocyclylalkyl, carbonate, ester, ether, heteroaralkyl, heterocyclyl, heterocyclylalkyl, hydrocarbyl, silyl, sulfone, or thioether. As used herein, the term “substituted” is contemplated to include all permissible substituents of organic compounds. In a broad aspect, the permissible substituents include acyclic and cyclic, branched and unbranched, carbocyclic and heterocyclic, aromatic and non-aromatic substituents of organic compounds. The permissible substituents can be one or more and the same or different for appropriate organic compounds. For purposes of this invention, the heteroatoms such as nitrogen may have hydrogen substituents and/or any permissible substituents of organic compounds described herein which satisfy the valences of the heteroatoms. Substituents can include any substituents described herein, for example, a halogen, a hydroxyl, a carbonyl (such as a carboxyl, an alkoxycarbonyl, a formyl, or an acyl), a thiocarbonyl (such as a thioester, a thioacetate, or a thioformate), an alkoxy, a phosphoryl, a phosphate, a phosphonate, a phosphinate, an amino, an amido, an amidine, an imine, a cyano, a nitro, an azido, a sulfhydryl, an alkylthio, a sulfate, a sulfonate, a sulfamoyl, a sulfonamido, a sulfonyl, a heterocyclyl, an aralkyl, or an aromatic or heteroaromatic moiety. In preferred embodiments, the substituents on substituted alkyls are selected from C₁₋₆ alkyl, C₃₋₆ cycloalkyl, halogen, carbonyl, cyano, or hydroxyl. In more preferred embodiments, the substituents on substituted alkyls are selected from fluoro, carbonyl, cyano, or hydroxyl. It will be understood by those skilled in the art that substituents can themselves be substituted, if appropriate. Unless specifically stated as “unsubstituted,” references to chemical moieties herein are understood to include substituted variants. For example, reference to an “aryl” group or moiety implicitly includes both substituted and unsubstituted variants.

The term “sulfonate” is art-recognized and refers to the group SO₃H, or a pharmaceutically acceptable salt thereof.

The term “sulfone” is art-recognized and refers to the group —S(O)₂—R^{A}, wherein R^{A} represents a hydrocarbyl.

The term “thioether,” as used herein, is equivalent to an ether, wherein the oxygen is replaced with a sulfur.

The term “symmetrical molecule,” as used herein, refers to molecules that are group symmetric or synthetic symmetric. The term “group symmetric,” as used herein, refers to molecules that have symmetry according to the group theory of molecular symmetry. The term “synthetic symmetric.” as used herein, refers to molecules that are selected such that no regioselective synthetic strategy is required.

The term “donor,” as used herein, refers to a molecular fragment that can be used in organic light emitting diodes and is likely to donate electrons from its highest occupied molecular orbital to an acceptor upon excitation. In preferred embodiments, donor contain substituted amino group. In an example embodiment, donors have an ionization potential greater than or equal to −6.5 eV.

The term “acceptor,” as used herein, refers to a molecular fragment that can be used in organic light emitting diodes and is likely to accept electrons into its lowest unoccupied molecular orbital from a donor that has been subject to excitation. In an example embodiment, acceptors have an electron affinity less than or equal to −0.5 eV.

The term “bridge,” as used herein, refers to a molecular fragment that can be included in a molecule which is covalently linked between acceptor and donor moieties. The bridge can, for example, be further conjugated to the acceptor moiety, the donor moiety, or both. Without being bound to any particular theory, it is believed that the bridge moiety can sterically restrict the acceptor and donor moieties into a specific configuration, thereby preventing the overlap between the conjugated n system of donor and acceptor moieties. Examples of suitable bridge moieties include phenyl, ethenyl, and ethynyl.

The term “multivalent,” as used herein, refers to a molecular fragment that is connected to at least two other molecular fragments. For example, a bridge moiety, is multivalent.

“ [symbol] ” or “*” as used herein, refers to a point of attachment between two atoms.

“Hole transport layer (HTL)” and like terms mean a layer made from a material which transports holes. High hole mobility is recommended. The HTL is used to help block passage of electrons transported by the emitting layer. Low electron affinity is typically required to block electrons. The HTL should desirably have larger triplets to block exciton migrations from an adjacent emissive layer (EML). Examples of HTL compounds include, but are not limited to, di(p-tolyl)aminophenyl]cyclohexane (TAPC), N,N-diphenyl-N,N-bis(3- methylphenyl)-1,1-biphenyl-4,4-diamine (TPD), and N,N′-diphenyl-N,N′-bis(1-naphthyl)-(1,1′-biphenyl)-4,4′-diamine (NPB, α-NPD).

“Emitting layer” and like terms mean a layer which emits light. In some embodiments, the emitting layer comprises a host material and guest material. The guest material can also be referred to as a dopant material, but the disclosure is not limited thereto. The host material could be bipolar or unipolar and may be used alone or by combination of two or more host materials. The opto-electrical properties of the host material may differ to which type of guest material (TADF, Phosphorescent or Fluorescent) is used. For Fluorescent guest materials, the host materials should have good spectral overlap between absorption of the guest material and emission of the host material to induce good Forster transfer to guest materials. For Phosphorescent guest materials, the host materials should have high triplet energy to confine triplets of the guest material. For TADF guest materials, the host materials should have both spectral overlap and higher triplet energy.

“Dopant” and like terms, refer to additive materials for carrier transporting layers, emitting layers or other layers. In carrier transporting layers, dopant and like terms perform as an electron acceptor or a donator that increases the conductivity of an organic layer of an organic electronic device, when added to the organic layer as an additive. Organic semiconductors may likewise be influenced, with regard to their electrical conductivity, by doping. Such organic semiconducting matrix materials may be made up either of compounds with electron-donor properties or of compounds with electron-acceptor properties. In emitting layers, dopant and like terms also mean the light emitting material which is dispersed in a matrix, for example, a host. When a triplet harvesting material is doped into an emitting layer or contained in an adjacent layer so as to improve exciton generation efficiency, it is named as assistant dopant. An assistant dopant may preferably shorten a lifetime of the exciton. The content of the assistant dopant in the light emitting layer or the adjacent layer is not particularly limited so long as the triplet harvesting material improves the exciton generation efficiency. The content of the assistant dopant in the light emitting layer is preferably higher than, more preferably at least twice than the light emitting material. In the light emitting layer, the content of the host material is preferably 50% by weight or more, the content of the assistant dopant is preferably from 5% by weight to less than 50% by weight, and the content of the light emitting material is preferably more than 0% by weight to less than 30% by weight, more preferably from 0% by weight to less than 10% by weight. The content of the assistant dopant in the adjacent layer may be more than 50% by weight and may be 100% by weight. In the case where a device comprising a triplet harvesting material in a light emitting layer or an adjacent layer has a higher light emission efficiency than a device without the triplet harvesting material, such triplet harvesting material functions as an assistant dopant. A light emitting layer comprising a host material, an assistant dopant and a light emitting material satisfies the following (A) and preferably satisfies the following (B):

ES1(A)>ES1(B)>ES1(C) (A)

ET1(A)>ET1(B) (B)

wherein ES1(A) represents a lowest excited singlet energy level of the host material; ES1(B) represents a lowest excited singlet energy level of the assistant dopant; ES1(C) represents a lowest excited singlet energy level of the light emitting material; ET1(A) represents a lowest excited triplet energy level at 77 K of the host material; and ET1(B) represents a lowest excited triplet energy level at 77 K of the assistant dopant. The assistant dopant has an energy difference ΔE_{ST} between a lowest singlet excited state and a lowest triplet excited state at 77 K of preferably 0.3 eV or less, more preferably 0.2 eV or less, still more preferably 0.1 eV or less.

In the compounds of this invention any atom not specifically designated as a particular isotope is meant to represent any stable isotope of that atom. Unless otherwise stated, when a position is designated specifically as “H” or “hydrogen”, the position is understood to have hydrogen at its natural abundance isotopic composition. Also, unless otherwise stated, when a position is designated specifically as “d” or “deuterium”, the position is understood to have deuterium at an abundance that is at least 3340 times greater than the natural abundance of deuterium, which is 0.015% (i.e., at least 50.1% incorporation of deuterium).

The term “isotopic enrichment factor” as used herein means the ratio between the isotopic abundance and the natural abundance of a specified isotope.

In various embodiments, compounds of this invention have an isotopic enrichment factor for each designated deuterium atom of at least 3500 (52.5% deuterium incorporation at each designated deuterium atom), at least 4000 (60% deuterium incorporation), at least 4500 (67.5% deuterium incorporation), at least 5000 (75% deuterium), at least 5500 (82.5% deuterium incorporation), at least 6000 (90% deuterium incorporation), at least 6333.3 (95% deuterium incorporation), at least 6466.7 (97% deuterium incorporation), at least 6600 (99% deuterium incorporation), or at least 6633.3 (99.5% deuterium incorporation).

The term “isotopologue” refers to a species that differs from a specific compound of this invention only in the isotopic composition thereof.

The term “compound,” when referring to a compound of this invention, refers to a collection of molecules having an identical chemical structure, except that there may be isotopic variation among the constituent atoms of the molecules. Thus, it will be clear to those of skill in the art that a compound represented by a particular chemical structure containing indicated deuterium atoms, will also contain lesser amounts of isotopologues having hydrogen atoms at one or more of the designated deuterium positions in that structure. The relative amount of such isotopologues in a compound of this invention will depend upon a number of factors including the isotopic purity of deuterated reagents used to make the compound and the efficiency of incorporation of deuterium in the various synthesis steps used to prepare the compound. However, as set forth above the relative amount of such isotopologues in toto will be less than 49.9% of the compound. In other embodiments, the relative amount of such isotopologues in toto will be less than 47.5%, less than 40%, less than 32.5%, less than 25%, less than 17.5%, less than 10%, less than 5%, less than 3%, less than 1%, or less than 0.5% of the compound.

“Substituted with deuterium” refers to the replacement of one or more hydrogen atoms with a corresponding number of deuterium atoms. “D” and “d” both refer to deuterium.

### (Principles of OLED)

OLEDs are typically composed of a layer of organic materials or compounds between two electrodes, an anode and a cathode. The organic molecules are electrically conductive as a result of delocalization of n electronics caused by conjugation over part or all of the molecule. When voltage is applied, electrons from the highest occupied molecular orbital (HOMO) present at the anode flow into the lowest unoccupied molecular orbital (LUMO) of the organic molecules present at the cathode. Removal of electrons from the HOMO is also referred to as inserting electron holes into the HOMO. Electrostatic forces bring the electrons and the holes towards each other until they recombine and form an exciton (which is the bound state of the electron and the hole). As the excited state decays and the energy levels of the electrons relax, radiation having a frequency in the visible spectrum is emitted. The frequency of this radiation depends on the band gap of the material, which is the difference in energy between the HOMO and the LUMO.

As electrons and holes are fermions with half integer spin, an exciton may either be in a singlet state or a triplet state depending on how the spins of the electron and hole have been combined. Statistically, three triplet excitons will be formed for each singlet exciton. Decay from triplet states is spin forbidden, which results in increases in the timescale of the transition and limits the internal efficiency of fluorescent devices. Phosphorescent organic light-emitting diodes make use of spin-orbit interactions to facilitate intersystem crossing between singlet and triplet states, thus obtaining emission from both singlet and triplet states and improving the internal efficiency.

One prototypical phosphorescent material is iridium tris(2-phenylpyridine) (Ir(ppy)₃) in which the excited state is a charge transfer from the Ir atom to the organic ligand. Such approaches have reduced the triplet lifetime to about several μs, several orders of magnitude slower than the radiative lifetimes of fully-allowed transitions such as fluorescence. Ir-based phosphors have proven to be acceptable for many display applications, but losses due to large triplet densities still prevent the application of OLEDs to solid-state lighting at higher brightness.

Thermally activated delayed fluorescence (TADF) seeks to minimize energetic splitting between singlet and triplet states (Δ, ΔE_{ST}). The reduction in exchange splitting from typical values of 0.4-0.7 eV to a gap of the order of the thermal energy (proportional to kBT, where kB represents the Boltzmann constant, and T represents temperature) means that thermal agitation can transfer population between singlet levels and triplet levels in a relevant timescale even if the coupling between states is small.

TADF molecules consist of donor and acceptor moieties connected directly by a covalent bond or via a conjugated linker (or “bridge”). A “donor” moiety is likely to transfer electrons from its HOMO upon excitation to the “acceptor” moiety. An “acceptor” moiety is likely to accept the electrons from the “donor” moiety into its LUMO. The donor-acceptor nature of TADF molecules results in low-lying excited states with charge-transfer character that exhibit very low ΔE_{ST}. Since thermal molecular motions can randomly vary the optical properties of donor-acceptor systems, a rigid three-dimensional arrangement of donor and acceptor moieties can be used to limit the non-radiative decay of the charge-transfer state by internal conversion during the lifetime of the excitation.

It is beneficial, therefore, to decrease ΔE_{ST}, and to create a system with increased reversed intersystem crossing (RISC) capable of exploiting triplet excitons. Such a system, it is believed, will result in increased quantum efficiency and decreased emission lifetimes. Systems with these features will be capable of emitting light without being subject to the rapid degradation prevalent in OLEDs known today.

In some embodiments of the present disclosure, the light emitting material of the present invention is, when excited thermally or by an electronic means, able to emit light in a UV region, light of blue, green, yellow or orange in a visible region, in a red region (e.g., about 420 nm to about 500 nm, about 500 nm to about 600 nm, or about 600 nm to about 700 nm) or in a near IR region.

In some embodiments of the present disclosure, the light emitting material of the present invention is, when excited thermally or by an electronic means, able to emit light of red or orange in a visible region (e.g., about 620 nm to about 780 nm, about 650 nm).

In some embodiments of the present disclosure, the light emitting material of the present invention is, when excited thermally or by an electronic means, able to emit light of orange or yellow in a visible region (e.g., about 570 nm to about 620 nm, about 590 nm, about 570 nm).

In some embodiments of the present disclosure, the light emitting material of the present invention is, when excited thermally or by an electronic means, able to emit light of green in a visible region (e.g., about 490 nm to about 575 nm, about 510 nm).

In some embodiments of the present disclosure, the light emitting material of the present invention is, when excited thermally or by an electronic means, able to emit light of blue in a visible region (e.g., about 400 nm to about 490 nm, about 475 nm).

In some embodiments of the present disclosure, the light emitting material of the present invention is, when excited thermally or by an electronic means, able to emit light in a UV region (e.g., about 280 to 400 nm).

In some embodiments of the present disclosure, the light emitting material of the present invention is, when excited thermally or by an electronic means, able to emit light in an IR region (e.g., about 780 nm to 2 μm).

### (Compound Screening)

Electronic characteristics of small-molecule chemical substance libraries can be calculated by known ab initio quantum chemistry calculation. For example, according to time-dependent density functional theory calculation using 6-31G* as a basis, and a functional group known as Becke's three parameters, Lee-Yang-Parr hybrid functionals, the Hartree-Fock equation (TD-DFT/B3LYP/6-31G*) is analyzed and molecular fractions (parts) having HOMO not lower than a specific threshold value and LUMO not higher than a specific threshold value can be screened, and the calculated triplet state of the parts is more than 2.75 eV.

With that, for example, in the presence of a HOMO energy (for example, ionizing potential) of −6.5 eV or more, a donor part (“D”) can be selected. On the other hand, for example, in the presence of a LUMO energy (for example, electron affinity) of −0.5 eV or less, an acceptor part (“A”) can be selected. A bridge part (“B”) is a strong conjugated system, for example, capable of strictly limiting the acceptor part and the donor part in a specific three-dimensional configuration, and therefore prevents the donor part and the acceptor part from overlapping in the pai-conjugated system.

In some embodiments, a compound library is screened using at least one of the following characteristics.
1. Light emission around a specific wavelength.
2. A triplet state over a calculated specific energy level.
3. ΔE_{ST} value lower than a specific value.
4. Quantum yield more than a specific value.
5. HOMO level.
6. LUMO level.

In some embodiments, the difference (ΔE_{ST}) between the lowest singlet excited state and the lowest triplet excited state at 77 K is less than about 0.5 eV, less than about 0.4 eV, less than about 0.3 eV, less than about 0.2 eV, or less than about 0.1 eV. In some embodiments, ΔE_{ST} value is less than about 0.09 eV, less than about 0.08 eV, less than about 0.07 eV, less than about 0.06 eV, less than about 0.05 eV, less than about 0.04 eV, less than about 0.03 eV, less than about 0.02 eV, or less than about 0.01 eV.

In some embodiments, the light emitting material of the present invention shows a quantum yield of more than 25%, for example, about 30%, about 35%, about 40%, about 45%, about 50%, about 55%, about 60%, about 65%, about 70%, about 75%, about 80%, about 85%, about 90%, about 95% or more.

### (Film Formation)

In some embodiments, a film containing the light emitting material of the present invention can be formed in a wet process. In a wet process, a solution prepared by dissolving the light emitting material of the present invention is applied onto a surface, and then the solvent is removed to form a film. The wet process includes a spin coating method, a slit coating method, an ink jet method (a spraying method), a gravure printing method, an offset printing method and flexographic printing method, which, however are not limitative. In the wet process, an appropriate organic solvent capable of dissolving the light emitting material of the present invention is selected and used. For example, a non-polar solvent such as an aromatic hydrocarbon solvent including toluene can be used, but the solvent usable herein is not limited thereto. In some embodiments, a substituent (for example, an alkyl group) capable of increasing the solubility in an organic solvent can be introduced into the compound to be contained in the light emitting material.

In some embodiments, a film containing the light emitting material of the present invention can be formed in a dry process. In some embodiments, a vacuum evaporation method is employable as a dry process, which, however, is not limitative. In the case where a vacuum evaporation method is employed, compounds to constitute a film can be co-evaporated from individual evaporation sources, or can be co-evaporated from a single evaporation source formed by mixing the compounds. In the case where a single evaporation source is used, a mixed powder prepared by mixing compound powders can be used, or a compression molded body prepared by compression-molding the mixed powder can be used, or a mixture prepared by heating and melting the constituent compounds and cooling the resulting melt can be used. In some embodiments, by co-evaporation under the condition where the evaporation rate (weight reduction rate) of the plural compounds contained in a single evaporation source is the same or is nearly the same, a film having a compositional ratio corresponding to the compositional ratio of the plural compounds contained in the evaporation source can be formed. When plural compounds are mixed in the same compositional ratio as the compositional ratio of the film to be formed to prepare an evaporation source, a film having a desired compositional ratio can be formed in a simplified manner. In some embodiments, the temperature at which the compounds to be co-evaporated has the same weight reduction ratio is specifically defined, and the temperature can be employed as the temperature of co-evaporation.

### [Use Examples of Light Emitting Material in the Present Disclosure]

### (Organic Light Emitting Diode)

One embodiment of the present invention relates to use of the light emitting material of the present invention as a light emitting material for organic light emitting devices. In some embodiments, the light emitting material of the present invention can be effectively used as a light emitting material in a light emitting layer in an organic light emitting device. In some embodiments, the light emitting material of the present invention includes delayed fluorescence (delayed fluorescent material) that emits delayed fluorescence. In some embodiments, the present invention provides a delayed fluorescent material containing the light emitting material of the present invention. In some embodiments, the present invention relates to use of the light emitting material of the present invention as a delayed fluorescent material. In some embodiments, the present invention relates to a method of generating delayed fluorescence from the light emitting material of the present invention. In some embodiments, an organic light emitting device containing, as a light emitting material therein, the light emitting material of the present invention emits delayed fluorescence and exhibits high luminous radiation efficiency.

In some embodiments of the light emitting material of the present invention, the donor compound, the acceptor compound and the light emitting compound are aligned in parallel to the substrate. In some embodiment, the substrate is a film-forming surface. In some embodiment, the alignment of the donor compound, the acceptor compound and the light emitting compound relative to the film-forming surface can have some influence on the propagation direction of light emitted by the aligned compounds, or can determine the direction. In some embodiments, by aligning the propagation direction of light emitted by the donor compound, the acceptor compound and the light emitting compound, the light extraction efficiency from the light emitting layer can be improved.

One embodiment of the present invention relates to an organic light emitting device. In some embodiments, the organic light emitting device includes a light emitting layer. In some embodiments, the light emitting layer contains, as a light emitting material therein, the light emitting material of the present invention. In some embodiments, the organic light emitting device is an organic photoluminescent device (organic PL device). In some embodiments, the organic light emitting device is an organic electroluminescent device (organic EL device). In some embodiments, the exciplex formed by the donor compound and the acceptor compound assists light irradiation from the other light emitting materials contained in the light emitting layer (as a so-called assist dopant). In some embodiments, the exciplex formed by the donor compound and the acceptor compound contained in the light emitting layer is in a lowest excited energy level, and is contained between the lowest excited single energy level of the host material contained in the light emitting layer and the lowest excited singlet energy level of the other light emitting materials contained in the light emitting layer.

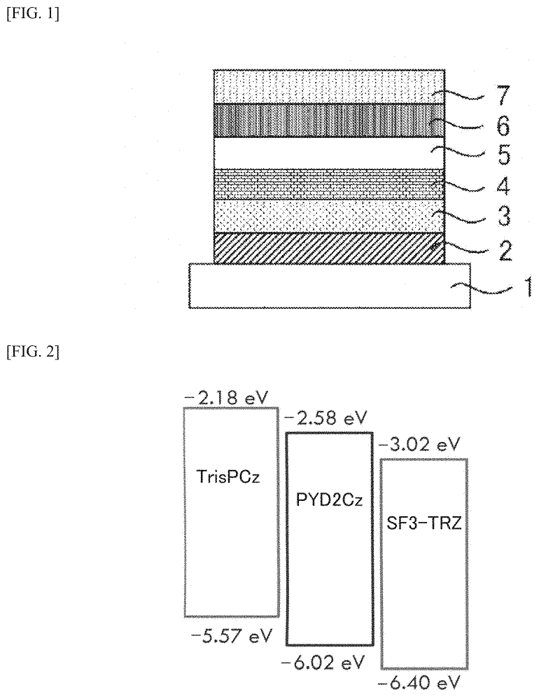

In some embodiments, the organic photoluminescent device comprises at least one light-emitting layer. In some embodiments, the organic electroluminescent device comprises at least an anode, a cathode, and an organic layer between the anode and the cathode. In some embodiments, the organic layer comprises at least a light-emitting layer. In some embodiments, the organic layer comprises only a light-emitting layer. In some embodiments, the organic layer, comprises one or more organic layers in addition to the light-emitting layer. Examples of the organic layer include a hole transporting layer, a hole injection layer, an electron barrier layer, a hole barrier layer, an electron injection layer, an electron transporting layer and an exciton barrier layer. In some embodiments, the hole transporting layer may be a hole injection and transporting layer having a hole injection function, and the electron transporting layer may be an electron injection and transporting layer having an electron injection function. An example of an organic electroluminescent device is shown in FIG. 1.

### (Substrate)

In some embodiments, the organic electroluminescent device of the invention is supported by a substrate, wherein the substrate is not particularly limited and may be any of those that have been commonly used in an organic electroluminescent device, for example those formed of glass, transparent plastics, quartz and silicon.

### (Anode)

In some embodiments, the anode of the organic electroluminescent device is made of a metal, an alloy, an electroconductive compound, or a combination thereof. In some embodiments, the metal, alloy, or electroconductive compound has a large work function (4 eV or more). In some embodiments, the metal is Au. In some embodiments, the electroconductive transparent material is selected from CuI, indium tin oxide (ITO), SnO₂, and ZnO. In some embodiments, an amorphous material capable of forming a transparent electroconductive film, such as IDIXO (In₂O₃—ZnO), is be used. In some embodiments, the anode is a thin film. In some embodiments the thin film is made by vapor deposition or sputtering. In some embodiments, the film is patterned by a photolithography method. In some embodiments, where the pattern may not require high accuracy (for example, approximately 100 μm or more), the pattern may be formed with a mask having a desired shape on vapor deposition or sputtering of the electrode material. In some embodiments, when a material can be applied as a coating, such as an organic electroconductive compound, a wet film forming method, such as a printing method and a coating method is used. In some embodiments, when the emitted light goes through the anode, the anode has a transmittance of more than 10%, and the anode has a sheet resistance of several hundred Ohm per square or less. In some embodiments, the thickness of the anode is from 10 to 1,000 nm. In some embodiments, the thickness of the anode is from 10 to 200 nm. In some embodiments, the thickness of the anode varies depending on the material used.

### (Cathode)

In some embodiments, the cathode is made of an electrode material a metal having a small work function (4 eV or less) (referred to as an electron injection metal), an alloy, an electroconductive compound, or a combination thereof. In some embodiments, the electrode material is selected from sodium, a sodium-potassium alloy, magnesium, lithium, a magnesium-cupper mixture, a magnesium-silver mixture, a magnesium-aluminum mixture, a magnesium-indium mixture, an aluminum-aluminum oxide (Al₂O₃) mixture, indium, a lithium-aluminum mixture, and a rare earth metal. In some embodiments, a mixture of an electron injection metal and a second metal that is a stable metal having a larger work function than the electron injection metal is used. In some embodiments, the mixture is selected from a magnesium-silver mixture, a magnesium-aluminum mixture, a magnesium-indium mixture, an aluminum-aluminum oxide (Al₂O₃) mixture, a lithium-aluminum mixture, and aluminum. In some embodiments, the mixture increases the electron injection property and the durability against oxidation. In some embodiments, the cathode is produced by forming the electrode material into a thin film by vapor deposition or sputtering. In some embodiments, the cathode has a sheet resistance of several hundred Ohm per square or less. In some embodiments, the thickness of the cathode ranges from 10 nm to 5 μm. In some embodiments, the thickness of the cathode ranges from 50 to 200 nm. In some embodiments, for transmitting the emitted light, any one of the anode and the cathode of the organic electroluminescent device is transparent or translucent. In some embodiments, the transparent or translucent electroluminescent devices enhances the light emission luminance.

In some embodiments, the cathode is formed with an electroconductive transparent material, as described for the anode, to form a transparent or translucent cathode. In some embodiments, a device comprises an anode and a cathode, both being transparent or translucent.

### (Light Emitting Layer)

In some embodiments, the light emitting layer is a layer where holes and electrons injected from the anode and the cathode, respectively, are recombined to form excitons. In some embodiments, the layer emits light.

In some embodiments, only a light emitting material is used as the light emitting layer. In some embodiments, the light emitting layer contains a light emitting material and a host material. In some embodiments, the light emitting material is an exciplex formed by a donor compound and an acceptor compound, or a light emitting compound. In some embodiments, for improving luminous radiation efficiency of an organic electroluminescent device and an organic photoluminescence device, the singlet exciton and the triplet exciton generated in a light emitting material is confined inside the light emitting material. In some embodiments, a host material is used in the light emitting layer in addition to a light emitting material therein. In some embodiments, the host material is an organic compound. In some embodiments, the organic compound has an excited singlet energy and an excited triplet energy, and at least one of them is higher than those in the light emitting material of the present invention. In some embodiments, the singlet exciton and the triplet exciton generated in the light emitting material of the present invention are confined in the molecules of the light emitting material of the present invention. In some embodiments, the singlet and triplet excitons are fully confined for improving luminous radiation efficiency. In some embodiments, although high luminous radiation efficiency is still attained, singlet excitons and triplet excitons are not fully confined, that is, a host material capable of attaining high luminous radiation efficiency can be used in the present invention with no specific limitation. In some embodiments, in the light emitting material in the light emitting layer of the device of the present invention, luminous radiation occurs. In some embodiments, radiated light includes both fluorescence and delayed fluorescence. In some embodiments, radiated light includes radiated light from a host material. In some embodiments, radiated light is composed of radiated light from a host material. In some embodiments, radiated light includes radiated light from an exciplex formed by a donor compound and an acceptor compound and from a light emitting compound, and radiated light from a host material. In some embodiment, a TADF molecule and a host material are used. In some embodiments, TADF is an assist dopant.

In some embodiments where a host material is used, the amount of the exciplex and the light emitting compound contained in the light emitting layer is 0.1% by weight or more. In some embodiments where a host material is used, the amount of the exciplex and the light emitting compound contained in the light emitting layer is 1% by weight or more. In some embodiments where a host material is used, the amount of the exciplex and the light emitting compound contained in the light emitting layer is 50% by weight or less. In some embodiments where a host material is used, the amount of the exciplex and the light emitting compound contained in the light emitting layer is 20% by weight or less. In some embodiments where a host material is used, the amount of the exciplex and the light emitting compound contained in the light emitting layer is 10% by weight or less.

In some embodiments, the host material in the light emitting layer is an organic compound having a hole transporting function and an electron transporting function. In some embodiments, the host material in the light emitting layer is an organic compound that prevents increase in the wavelength of radiated light. In some embodiments, the host material in the light emitting layer is an organic compound having a high glass transition temperature.

In some embodiments, the light emitting layer contains at least two TADF molecules differing in the structure. For example, the light emitting layer can contain three kinds of materials, a host material, a first TADF molecule and a second TADF molecule whose excited singlet energy level is higher in that order. At that time, the first TADF molecule and the second TADF molecule are preferably such that the difference ΔE_{ST} between the lowest excited singlet energy level and the lowest excited triplet energy level at 77 K thereof is 0.3 eV or less, more preferably 0.25 eV or less, even more preferably 0.2 eV or less, further more preferably 0.15 eV or less, further more preferably 0.1 eV or less, further more preferably 0.07 eV or less, further more preferably 0.05 eV or less, further more preferably 0.03 eV or less, especially more preferably 0.01 eV or less. The content of the first TADF molecule in the light emitting layer is preferably larger than the content of the second TADF molecule therein. The content of the host material in the light emitting layer is preferably larger than the content of the second TADF molecule therein. The content of the first TADF molecule in the light emitting layer can be larger than the content of the host material therein, or can be smaller than or the same as the latter. In some embodiments, the composition in the light emitting layer can be 10 to 70% by weight of the host material, 10 to 80% by weight of the TADF molecule, and 0.1 to 30% by weight of the second TADF molecule. In some embodiments, the composition in the light emitting layer can be 20 to 45% by weight of the host material, 50 to 75% by weight of the first TADF molecule, and 5 to 20% by weight of the second TADF molecule. In some embodiments, the photoluminescence quantum yield φPL1(A) by photoexcitation of the co-deposited film of the first TADF molecule and the host material (the content of the first TADF molecule in the co-deposited film=A % by weight) and the photoluminescence quantum yield φPL2(A) by photoexcitation of the co-deposited film of the second TADF molecule and the host material (the content of the second TADF molecule in the co-deposited film=A % by weight) satisfy a relational formula φPL1(A)>φPL2(A). In some embodiments, the photoluminescence quantum yield φPL2(B) by photoexcitation of the co-deposited film of the second TADF molecule and the host material (the content of the second TADF molecule in the co-deposited film=B % by weight) and the photoluminescence quantum yield φPL2(100) by photoexcitation of the single film of the second TADF molecule satisfy a relational formula φPL2(B)>φPL2(100). In some embodiments, the light emitting layer can contain three TADF molecules differing in the structure. The exciplex and the light emitting compound in the present invention can be any of plural TADF compounds contained in the light emitting layer.

In some embodiments, the light emitting layer can be composed of a material selected from a group consisting of a host material, an assist dopant and a light emitting material. In some embodiments, the light emitting layer does not contain a metal element. In some embodiments, the light emitting layer can be composed of a material composed of atoms alone selected from the group consisting of a carbon atom, a hydrogen atom, a nitrogen atom, an oxygen atom and a sulfur atom. Or the light emitting layer can be composed of a material composed of atoms alone selected from the group consisting of a carbon atom, a hydrogen atom and a nitrogen atom.

When the light emitting layer contains a TADF material, the TADF material can be a known delayed fluorescent material. Preferred delayed fluorescent materials are compounds included in the general formulae described in WO2013/154064, paragraphs 0008 to 0048 and 0095 to 0133: WO2013/011954, paragraphs 0007 to 0047 and 0073-0085; WO2013/011955, paragraphs 0007 to 0033 and 0059 to 0066; WO2013/081088, paragraphs 0008 to 0071 and 0118 to 0133; JP 2013-256490 A, paragraphs 0009 to 0046 and 0093 to 0134; JP 2013-116975 A, paragraphs 0008 to 0020 and 0038 to 0040: WO2013/133359, paragraphs 0007 to 0032 and 0079 to 0084; WO2013/161437, paragraphs 0008 to 0054 and 0101-0121; JP 2014-9352 A, paragraphs 0007 to 0041 and 0060 to 0069; and JP 2014-9224 A, paragraphs 0008 to 0048 and 0067 to 0076; JP 2017-119663 A, paragraphs 0013 to 0025; JP 2017-119664 A, paragraphs 0013 to 0026; JP 2017-222623 A, paragraphs 0012 to 0025; JP 2017-226838 A, paragraphs 0010 to 0050; JP 2018-100411 A, paragraphs 0012 to 0043; WO2018/047853, paragraphs 0016 to 0044; and exemplary compounds therein capable of radiating delayed fluorescence are especially preferred. In addition, light-emitting materials capable of radiating delayed fluorescence, as described in JP 2013-253121 A, WO2013/133359, WO2014/034535, WO2014/115743, WO2014/122895, WO2014/126200, WO2014/136758. WO2014/133121, WO2014/136860, WO2014/196585, WO2014/189122, WO2014/168101, WO2015/008580, WO2014/203840, WO2015/002213, WO2015/016200, WO2015/019725, WO2015/072470, WO2015/108049, WO2015/080182, WO2015/072537, WO2015/080183, JP 2015-129240 A, WO2015/129714, WO2015/129715, WO2015/133501, WO2015/136880, WO2015/137244, WO2015/137202, WO2015/137136, WO2015/146541 and WO2015/159541, are also preferably employed. These patent publications described in this paragraph are hereby incorporated as a part of this description by reference.

### (Injection Layer)

An injection layer is a layer between the electrode and the organic layer. In some embodiments, the injection layer decreases the driving voltage and enhances the light emission luminance. In some embodiments, the injection layer includes a hole injection layer and an electron injection layer. The injection layer can be positioned between the anode and the light-emitting layer or the hole transporting layer, and between the cathode and the light-emitting layer or the electron transporting layer. In some embodiments, an injection layer is present. In some embodiments, no injection layer is present.

Preferred compound examples for use as a hole injection material are shown below.

### MoO₃,

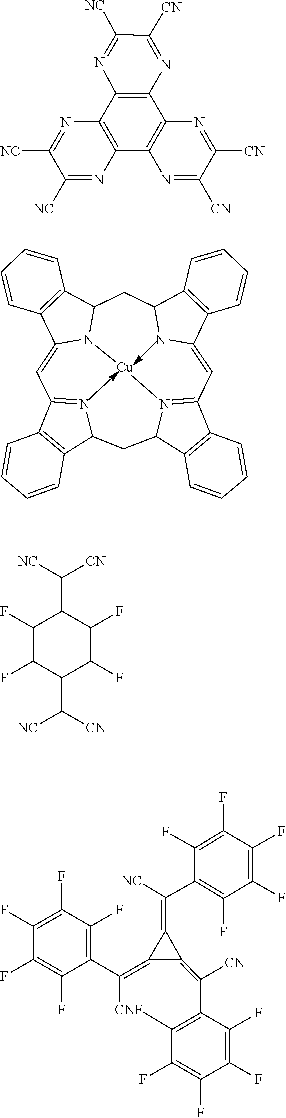

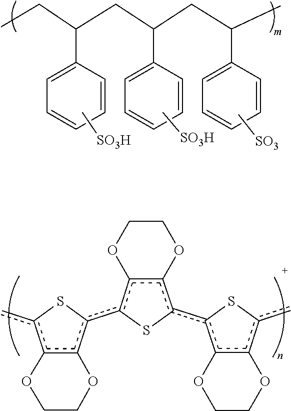

Next, preferred compound examples for use as an electron injection material are shown below.

LiF, CsF,

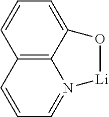

### (Barrier Layer)

A barrier layer is a layer capable of inhibiting charges (electrons or holes) and/or excitons present in the light-emitting layer from being diffused outside the light-emitting layer. In some embodiments, the electron barrier layer is between the light-emitting layer and the hole transporting layer, and inhibits electrons from passing through the light-emitting layer toward the hole transporting layer. In some embodiments, the hole barrier layer is between the light-emitting layer and the electron transporting layer, and inhibits holes from passing through the light-emitting layer toward the electron transporting layer. In some embodiments, the barrier layer inhibits excitons from being diffused outside the light-emitting layer. In some embodiments, the electron barrier layer and the hole barrier layer are exciton barrier layers. As used herein, the term “electron barrier layer” or “exciton barrier layer” includes a layer that has the functions of both electron barrier layer and of an exciton barrier layer.

### (Hole Barrier Layer)

A hole barrier layer acts as an electron transporting layer. In some embodiments, the hole barrier layer inhibits holes from reaching the electron transporting layer while transporting electrons. In some embodiments, the hole barrier layer enhances the recombination probability of electrons and holes in the light-emitting layer. The material for the hole barrier layer may be the same materials as the ones described for the electron transporting layer.

Preferred compound examples for use for the hole barrier layer are shown below.

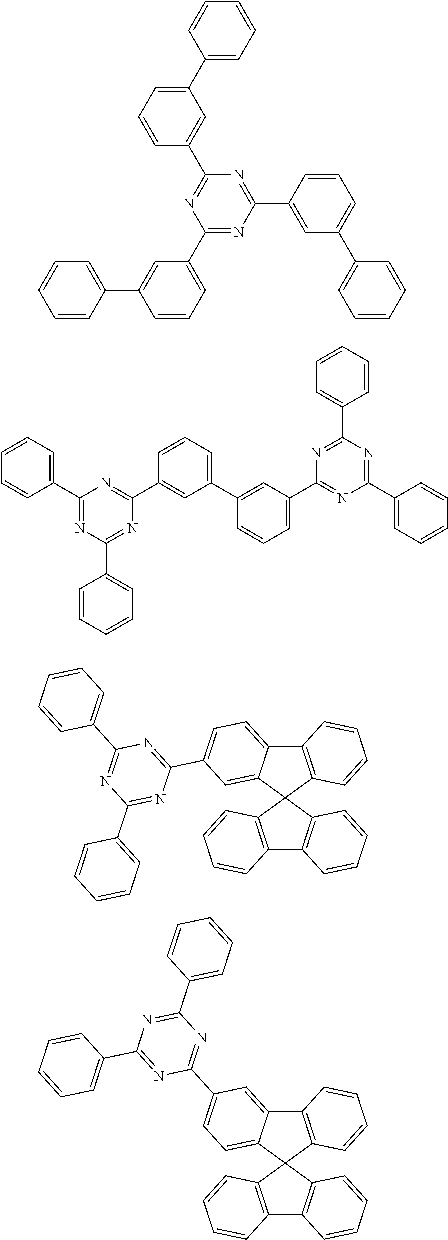

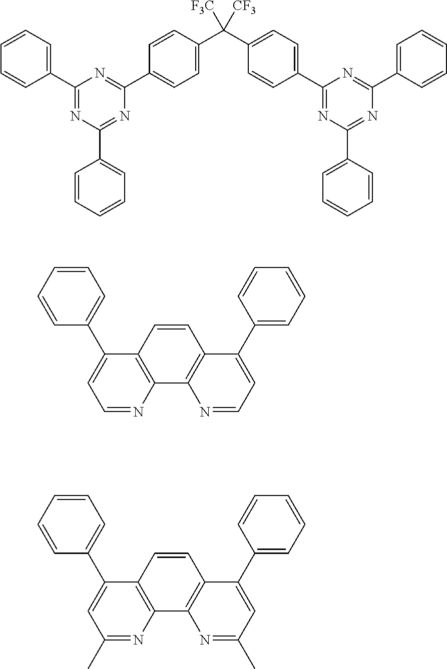 [SMILES: FC(F)(F)C(c1ccc(-c2nc(-c3ccccc3)nc(-c3ccccc3)n2)cc1)(c1ccc(-c2nc(-c3ccccc3)nc(-c3ccccc3)n2)cc1)C(F)(F)F ; c1ccc(-c2ccnc3c2ccc2c(-c4ccccc4)ccnc23)cc1 ; Cc1cc(-c2ccccc2)c2ccc3c(-c4ccccc4)cc(C)nc3c2n1]

### (Electron Barrier Layer)

An electron barrier layer transports holes. In some embodiments, the electron barrier layer inhibits electrons from reaching the hole transporting layer while transporting holes. In some embodiments, the electron barrier layer enhances the recombination probability of electrons and holes in the light-emitting layer. The materials for use for the electron barrier layer may be the same materials as those mentioned hereinabove for the hole transporting layer.

Preferred compound examples for use as the electron barrier material are shown below.

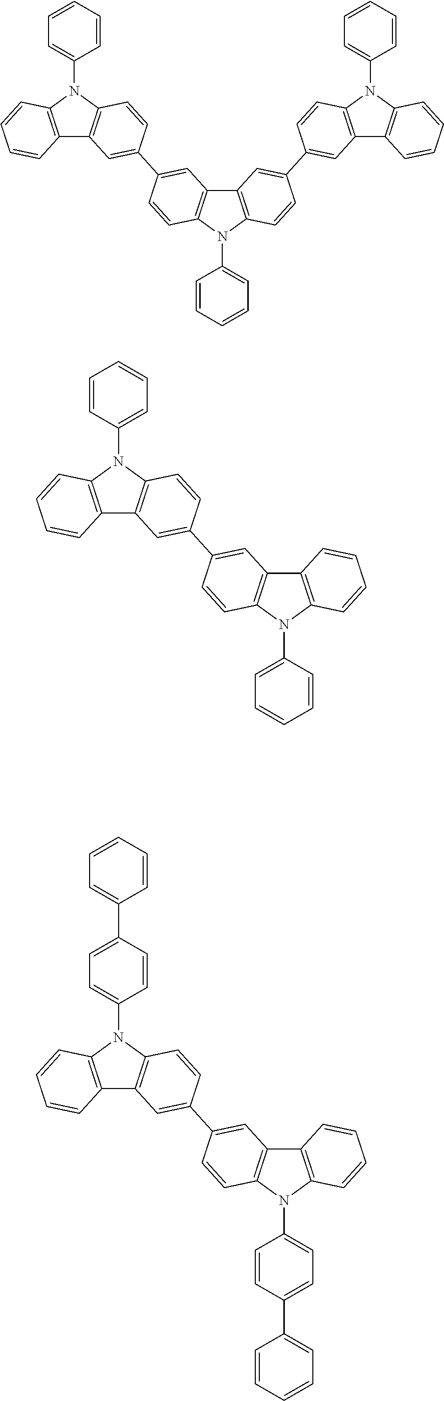 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1ccc(-n2c3ccccc3c3cc(-c4ccc5c(c4)c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

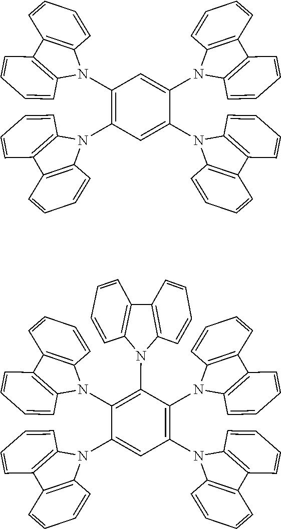 [SMILES: c1ccc2c(c1)c1ccccc1n2-c1cc(-n2c3ccccc3c3ccccc32)c(-n2c3ccccc3c3ccccc32)cc1-n1c2ccccc2c2ccccc21 ; c1ccc2c(c1)c1ccccc1n2-c1cc(-n2c3ccccc3c3ccccc32)c(-n2c3ccccc3c3ccccc32)c(-n2c3ccccc3c3ccccc32)c1-n1c2ccccc2c2ccccc21]

### (Exciton Barrier Layer)

An exciton barrier layer inhibits excitons generated through recombination of holes and electrons in the light-emitting layer from being diffused to the charge transporting layer. In some embodiments, the exciton barrier layer enables effective confinement of excitons in the light-emitting layer. In some embodiments, the light emission efficiency of the device is enhanced. In some embodiments, the exciton barrier layer is adjacent to the light-emitting layer on any of the side of the anode and the side of the cathode, and on both the sides. In some embodiments, where the exciton barrier layer is on the side of the anode, the layer can be between the hole transporting layer and the light-emitting layer and adjacent to the light-emitting layer. In some embodiments, where the exciton barrier layer is on the side of the cathode, the layer can be between the light-emitting layer and the cathode and adjacent to the light-emitting layer. In some embodiments, a hole injection layer, an electron barrier layer, or a similar layer is between the anode and the exciton barrier layer that is adjacent to the light-emitting layer on the side of the anode. In some embodiments, a hole injection layer, an electron barrier layer, a hole barrier layer, or a similar layer is between the cathode and the exciton barrier layer that is adjacent to the light-emitting layer on the side of the cathode. In some embodiments, the exciton barrier layer comprises excited singlet energy and excited triplet energy, at least one of which is higher than the excited singlet energy and the excited triplet energy of the light-emitting material, respectively.

### (Hole Transporting Layer)

The hole transporting layer comprises a hole transporting material. In some embodiments, the hole transporting laver is a single layer. In some embodiments, the hole transporting layer comprises a plurality of layers.

In some embodiments, the hole transporting material has one of injection or transporting property of holes and barrier property of electrons. In some embodiments, the hole transporting material is an organic material. In some embodiments, the hole transporting material is an inorganic material. Examples of known hole transporting materials that may be used herein include but are not limited to a triazole derivative, an oxadiazole derivative, an imidazole derivative, a carbazole derivative, an indolocarbazole derivative, a polyarylalkane derivative, a pyrazoline derivative, a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, an aniline copolymer and an electroconductive polymer oligomer, particularly a thiophene oligomer, or a combination thereof. In some embodiments, the hole transporting material is selected from a porphyrin compound, an aromatic tertiary amine compound, and a styrylamine compound. In some embodiments, the hole transporting material is an aromatic tertiary amine compound. Preferred compound examples for use as the hole transporting material are shown below.

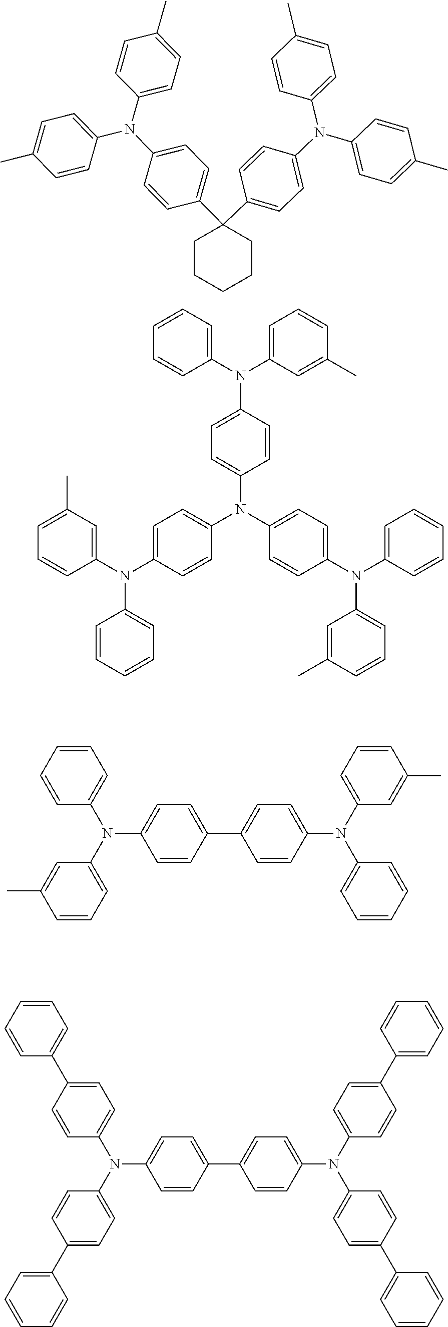

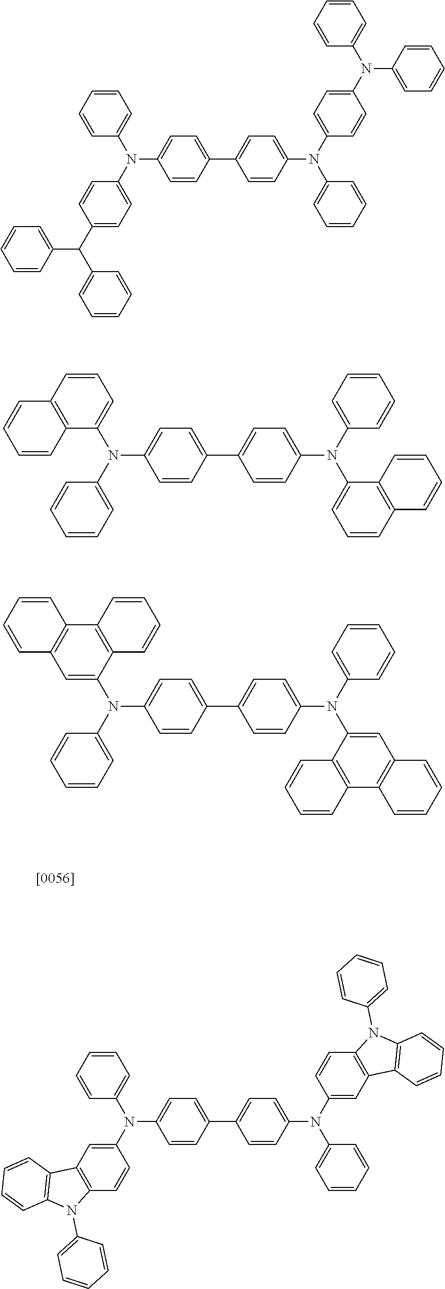 [SMILES: c1ccc(C(c2ccccc2)c2ccc(N(c3ccccc3)c3ccc(-c4ccc(N(c5ccccc5)c5ccc(N(c6ccccc6)c6ccccc6)cc5)cc4)cc3)cc2)cc1 ; c1ccc(N(c2ccc(-c3ccc(N(c4ccccc4)c4cccc5ccccc45)cc3)cc2)c2cccc3ccccc23)cc1 ; c1ccc(N(c2ccc(-c3ccc(N(c4ccccc4)c4cc5ccccc5c5ccccc45)cc3)cc2)c2cc3ccccc3c3ccccc23)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

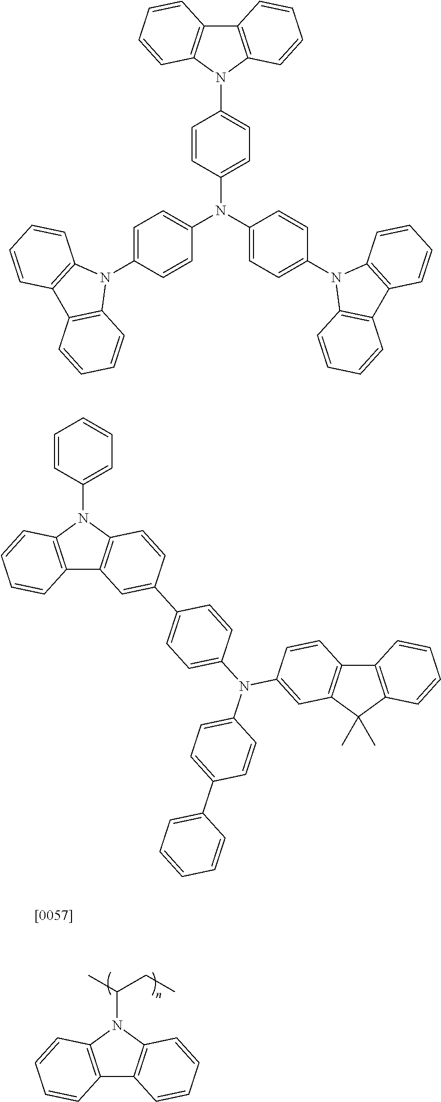

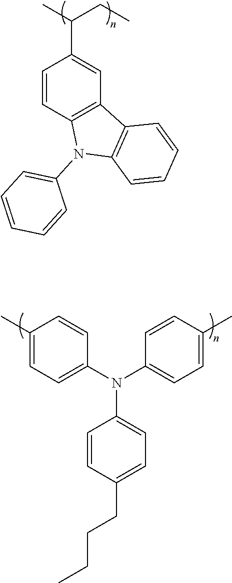

### (Electron Transporting Layer)

The electron transporting layer comprises an electron transporting material. In some embodiments, the electron transporting layer is a single layer. In some embodiments, the electron transporting layer comprises a plurality of layers.

In some embodiments, the electron transporting material needs only to have a function of transporting electrons, which are injected from the cathode, to the light-emitting layer. In some embodiments, the electron transporting material also functions as a hole barrier material. Examples of the electron transporting layer that may be used herein include but are not limited to a nitro-substituted fluorene derivative, a diphenylquinone derivative, a thiopyran dioxide derivative, carbodiimide, a fluorenylidene methane derivative, anthraquinodimethane, an anthrone derivatives, an oxadiazole derivative, an azole derivative, an azine derivative, or a combination thereof, or a polymer thereof. In some embodiments, the electron transporting material is a thiadiazole derivative, or a quinoxaline derivative. In some embodiments, the electron transporting material is a polymer material. Preferred compound examples for use as the electron transporting material are shown below.

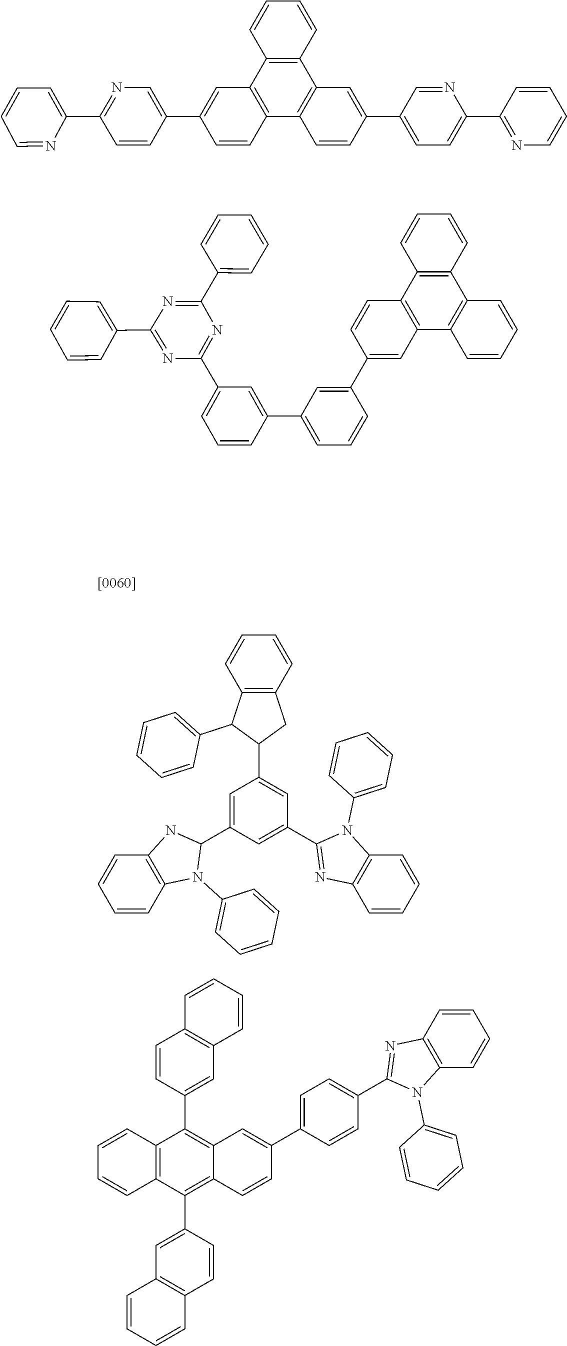

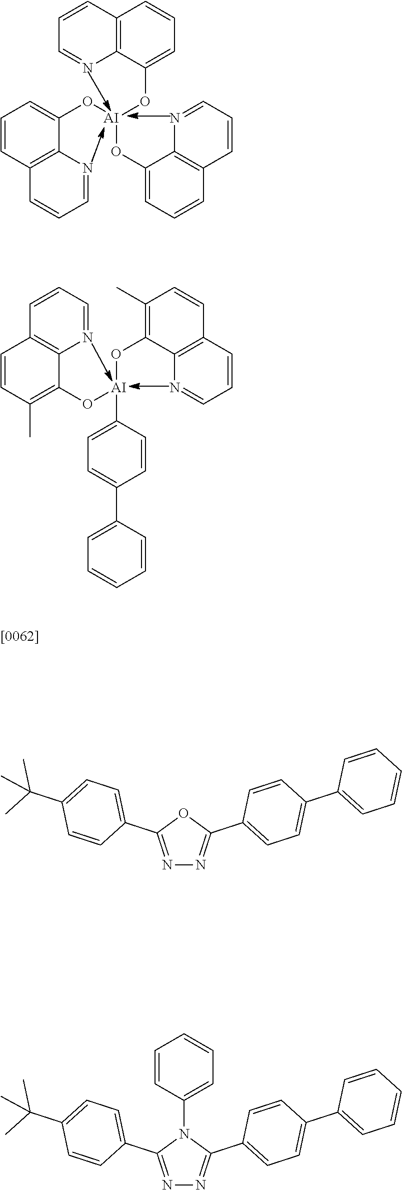

Preferred examples of compounds usable as materials that can be added to each organic layer are shown below.

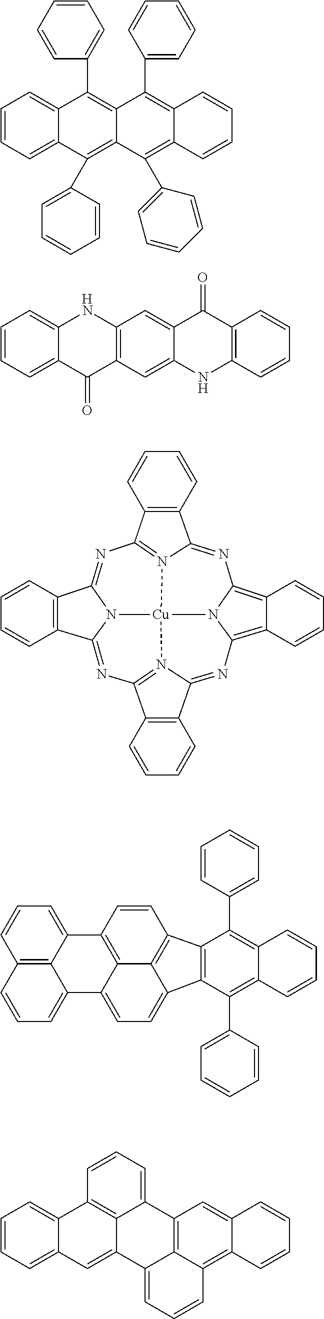

Hereinunder preferred materials for use in an organic electroluminescent device are specifically shown. However, the materials usable in the present invention should not be limitatively interpreted by the following exemplary compounds. Compounds that are exemplified as materials having a specific function can also be used as materials having any other function.

### (Devices)

In some embodiments, the light-emitting layers are incorporated into a device. For example, the device includes, but is not limited to an OLED bulb, an OLED lamp, a television screen, a computer monitor, a mobile phone, and a tablet.

In some embodiments, an electronic device comprises an OLED comprising an anode, a cathode, and at least one organic layer comprising a light emitting layer between the anode and the cathode.

In some embodiments, compositions described herein may be incorporated into various light-sensitive or light-activated devices, such as OLEDs or photovoltaic devices. In some embodiments, the composition may be useful in facilitating charge transfer or energy transfer within a device and/or as a hole-transport material. The device may be, for example, an organic light-emitting diode (OLED), an organic integrated circuit (OIC), an organic field-effect transistor (O-FET), an organic thin-film transistor (O-TFT), an organic light-emitting transistor (O-LET), an organic solar cell (O-SC), an organic optical detector, an organic photoreceptor, an organic field-quench device (O-FQD), a light-emitting electrochemical cell (LEC) or an organic laser diode (O-laser).

### (Bulbs or Lamps)

In some embodiments, an electronic device comprises an OLED comprising an anode, a cathode, and at least one organic layer comprising a light emitting layer between the anode and the cathode.

In some embodiments, a device comprises OLEDs that differ in color. In some embodiments, a device comprises an array comprising a combination of OLEDs. In some embodiments, the combination of OLEDs is a combination of three colors (e.g., RGB). In some embodiments, the combination of OLEDs is a combination of colors that are not red, green, or blue (for example, orange and yellow green). In some embodiments, the combination of OLEDs is a combination of two, four, or more colors.

In some embodiments, a device is an OLED light comprising:

a circuit board having a first side with a mounting surface and an opposing second side, and defining at least one aperture:

at least one OLED on the mounting surface, the at least one OLED configured to emanate light, comprising an anode, a cathode, and at least one organic layer comprising a light emitting layer between the anode and the cathode;

a housing for the circuit board; and

at least one connector arranged at an end of the housing, the housing and the connector defining a package adapted for installation in a light fixture.

In some embodiments, the OLED light comprises a plurality of OLEDs mounted on a circuit board such that light emanates in a plurality of directions. In some embodiments, a portion of the light emanated in a first direction is deflected to emanate in a second direction. In some embodiments, a reflector is used to deflect the light emanated in a first direction.

### (Displays or Screens)

In some embodiments, the light-emitting layer in the present invention can be used in a screen or a display. In some embodiments, the compounds in the present invention are deposited onto a substrate using a process including, but not limited to, vacuum evaporation, deposition, vapor deposition, or chemical vapor deposition (CVD). In some embodiments, the substrate is a photoplate structure useful in a two-sided etch that provides a unique aspect ratio pixel. The screen (which may also be referred to as a mask) is used in a process in the manufacturing of OLED displays. The corresponding artwork pattern design facilitates a very steep and narrow tie-bar between the pixels in the vertical direction and a large, sweeping bevel opening in the horizontal direction. This allows the close patterning of pixels needed for high definition displays while optimizing the chemical deposition onto a TFT backplane.

The internal patterning of the pixel allows the construction of a 3-dimensional pixel opening with varying aspect ratios in the horizontal and vertical directions. Additionally, the use of imaged “stripes” or halftone circles within the pixel area inhibits etching in specific areas until these specific patterns are undercut and fall off the substrate. At that point, the entire pixel area is subjected to a similar etch rate but the depths are varying depending on the halftone pattern. Varying the size and spacing of the halftone pattern allows etching to be inhibited at different rates within the pixel allowing for a localized deeper etch needed to create steep vertical bevels.

A preferred material for the deposition mask is invar. Invar is a metal alloy that is cold rolled into long thin sheet in a steel mill. Invar cannot be electrodeposited onto a rotating mandrel as the nickel mask. A preferred and more cost feasible method for forming the open areas in the mask used for deposition is through a wet chemical etching.

In some embodiments, a screen or display pattern is a pixel matrix on a substrate. In some embodiments, a screen or display pattern is fabricated using lithography (e.g., photolithography and e-beam lithography). In some embodiments, a screen or display pattern is fabricated using a wet chemical etch. In further embodiments, a screen or display pattern is fabricated using plasma etching.

### (Methods of Manufacturing Devices)

An OLED display is generally manufactured by forming a large mother panel and then cutting the mother panel in units of cell panels. In general, each of the cell panels on the mother panel is formed by forming a thin film transistor (TFT) including an active layer and a source/drain electrode on a base substrate, applying a planarization film to the TFT, and sequentially forming a pixel electrode, a light-emitting layer, a counter electrode, and an encapsulation layer, and then is cut from the mother panel.

An OLED display is generally manufactured by forming a large mother panel and then cutting the mother panel in units of cell panels. In general, each of the cell panels on the mother panel is formed by forming a thin film transistor (TFT) including an active layer and a source/drain electrode on a base substrate, applying a planarization film to the TFT, and sequentially forming a pixel electrode, a light-emitting layer, a counter electrode, and an encapsulation layer, and then is cut from the mother panel.

In another aspect, provided herein is a method of manufacturing an organic light-emitting diode (OLED) display, the method comprising:

forming a barrier layer on a base substrate of a mother panel:

forming a plurality of display units in units of cell panels on the barrier layer:

forming an encapsulation layer on each of the display units of the cell panels; and

applying an organic film to an interface portion between the cell panels.

In some embodiments, the barrier layer is an inorganic film formed of, for example, SiNx, and an edge portion of the barrier layer is covered with an organic film formed of polyimide or acryl. In some embodiments, the organic film helps the mother panel to be softly cut in units of the cell panel.

In some embodiments, the thin film transistor (TFT) layer includes a light-emitting layer, a gate electrode, and a source/drain electrode. Each of the plurality of display units may include a thin film transistor (TFT) layer, a planarization film formed on the TFT layer, and a light-emitting unit formed on the planarization film, wherein the organic film applied to the interface portion is formed of a same material as a material of the planarization film and is formed at a same time as the planarization film is formed. In some embodiments, a light-emitting unit is connected to the TFT layer with a passivation layer and a planarization film therebetween and an encapsulation layer that covers and protects the light-emitting unit. In some embodiments of the method of manufacturing, the organic film contacts neither the display units nor the encapsulation layer.

Each of the organic film and the planarization film may include any one of polyimide and acryl. In some embodiments, the barrier layer may be an inorganic film. In some embodiments, the base substrate may be formed of polyimide. The method may further include, before the forming of the barrier layer on one surface of the base substrate formed of polyimide, attaching a carrier substrate formed of a glass material to another surface of the base substrate, and before the cutting along the interface portion, separating the carrier substrate from the base substrate. In some embodiments, the OLED display is a flexible display.

In some embodiments, the passivation layer is an organic film disposed on the TFT layer to cover the TFT layer. In some embodiments, the planarization film is an organic film formed on the passivation layer. In some embodiments, the planarization film is formed of polyimide or acryl, like the organic film formed on the edge portion of the barrier layer. In some embodiments, the planarization film and the organic film are simultaneously formed when the OLED display is manufactured. In some embodiments, the organic film may be formed on the edge portion of the barrier layer such that a portion of the organic film directly contacts the base substrate and a remaining portion of the organic film contacts the barrier layer while surrounding the edge portion of the barrier layer.

In some embodiments, the light-emitting layer includes a pixel electrode, a counter electrode, and an organic light-emitting layer disposed between the pixel electrode and the counter electrode. In some embodiments, the pixel electrode is connected to the source/drain electrode of the TFT layer.

In some embodiments, when a voltage is applied to the pixel electrode through the TFT layer, an appropriate voltage is formed between the pixel electrode and the counter electrode, and thus the organic light-emitting layer emits light, thereby forming an image. Hereinafter, an image forming unit including the TFT layer and the light-emitting unit is referred to as a display unit.

In some embodiments, the encapsulation layer that covers the display unit and prevents penetration of external moisture may be formed to have a thin film encapsulation structure in which an organic film and an inorganic film are alternately stacked. In some embodiments, the encapsulation layer has a thin film encapsulation structure in which a plurality of thin films are stacked. In some embodiments, the organic film applied to the interface portion is spaced apart from each of the plurality of display units. In some embodiments, the organic film is formed such that a portion of the organic film directly contacts the base substrate and a remaining portion of the organic film contacts the barrier layer while surrounding an edge portion of the barrier layer.

In one embodiment, the OLED display is flexible and uses the soft base substrate formed of polyimide. In some embodiments, the base substrate is formed on a carrier substrate formed of a glass material, and then the carrier substrate is separated.

In some embodiments, the barrier layer is formed on a surface of the base substrate opposite to the carrier substrate. In one embodiment, the barrier layer is patterned according to a size of each of the cell panels. For example, while the base substrate is formed over the entire surface of a mother panel, the barrier layer is formed according to a size of each of the cell panels, and thus a groove is formed at an interface portion between the barrier layers of the cell panels. Each of the cell panels can be cut along the groove.

In some embodiments, the method of manufacture further comprises cutting along the interface portion, wherein a groove is formed in the barrier layer, wherein at least a portion of the organic film is formed in the groove, and wherein the groove does not penetrate into the base substrate. In some embodiments, the TFT layer of each of the cell panels is formed, and the passivation layer which is an inorganic film and the planarization film which is an organic film are disposed on the TFT layer to cover the TFT layer. At the same time as the planarization film formed of, for example, polyimide or acryl is formed, the groove at the interface portion is covered with the organic film formed of, for example, polyimide or acryl. This is to prevent cracks from occurring by allowing the organic film to absorb an impact generated when each of the cell panels is cut along the groove at the interface portion. That is, if the entire barrier layer is entirely exposed without the organic film, an impact generated when each of the cell panels is cut along the groove at the interface portion is transferred to the barrier layer, thereby increasing the risk of cracks. However, in one embodiment, since the groove at the interface portion between the barrier layers is covered with the organic film and the organic film absorbs an impact that would otherwise be transferred to the barrier layer, each of the cell panels may be softly cut and cracks may be prevented from occurring in the barrier layer. In one embodiment, the organic film covering the groove at the interface portion and the planarization film are spaced apart from each other. For example, if the organic film and the planarization film are connected to each other as one layer, since external moisture may penetrate into the display unit through the planarization film and a portion where the organic film remains, the organic film and the planarization film are spaced apart from each other such that the organic film is spaced apart from the display unit.

In some embodiments, the display unit is formed by forming the light-emitting unit, and the encapsulation layer is disposed on the display unit to cover the display unit. As such, once the mother panel is completely manufactured, the carrier substrate that supports the base substrate is separated from the base substrate. In some embodiments, when a laser beam is emitted toward the carrier substrate, the carrier substrate is separated from the base substrate due to a difference in a thermal expansion coefficient between the carrier substrate and the base substrate.

In some embodiments, the mother panel is cut in units of the cell panels. In some embodiments, the mother panel is cut along an interface portion between the cell panels by using a cutter. In some embodiments, since the groove at the interface portion along which the mother panel is cut is covered with the organic film, the organic film absorbs an impact during the cutting. In some embodiments, cracks may be prevented from occurring in the barrier layer during the cutting.

In some embodiments, the methods reduce a defect rate of a product and stabilize its quality.

Another aspect is an OLED display including, a barrier layer that is formed on a base substrate; a display unit that is formed on the barrier layer; an encapsulation layer that is formed on the display unit; and an organic film that is applied to an edge portion of the barrier layer.

### EXAMPLES

### General Information Relating to Analysis Method:

The characteristics of the present invention are specifically described with reference to the following Examples. The materials, the steps and the procedures shown below can be appropriately modified unless otherwise departing from the essential feature of the present invention. Accordingly, the range of the present invention is not interpreted to be limited to the specific embodiments shown below. Sample characteristics were evaluated, using NMR (Bruker's nuclear magnetic resonance 500 MHz), LC/MS (Waters' liquid chromatography mass spectrometer), AC3 (by Riken Keiki), high-performance UV/Vis/NIR spectrophotometer (Perkin Elmer's Lambda 950), fluorescence spectrophotometer (Horiba's FluoroMax-4), photonic multichannel analyzer (Hamamatsu Photonics' PMA-12 C10027-01), absolute PL quantum yield measuring system (Hamamatsu Photonics' C11347), automatic current voltage luminance measuring system (System Engineering's ETS-170), lifetime measuring system (System Engineering's EAS-26C) and streak camera (Hamamatsu Photonics' Model C4334).

### (Example 1) Thin Film Preparation and Evaluation—1—

Under the condition of a vacuum degree of 10⁻³ Pa or less, a donor compound TrisPCz, an acceptor compound SF3-TRZ and an adjustment compound PYD2Cz were vapor-deposited on a quartz substrate at a ratio by mass of 1/1/1 to prepare a thin film DAN having a thickness of 70 nm.

Under the same condition, TrisPCz only was vapor-deposited to prepare a thin film D.

Under the same condition. SF3-TRZ only was vapor-deposited to prepare a thin film A.

Under the same condition, PYD2Cz only was vapor-deposited to prepare a thin film N.

Under the same condition, TrisPCz and SF3-TRZ were vapor-deposited at a ratio by mass of 1/1 to prepare a thin film DA.

Under the same condition, TrisPCz and PYD2Cz were vapor-deposited at a ratio by mass of 1/1 to prepare a thin film DN.

Under the same condition, SF3-TRZ and PYD2Cz were vapor-deposited at a ratio by mass of 1/1 to prepare a thin film AN.

The energy level of each compound used in the light emitting layer in Example 1 is shown in FIG. 2. The thin film DAN is a light emitting material satisfying the relationship of the formula (A), the formula (B1) and the formula (B2).

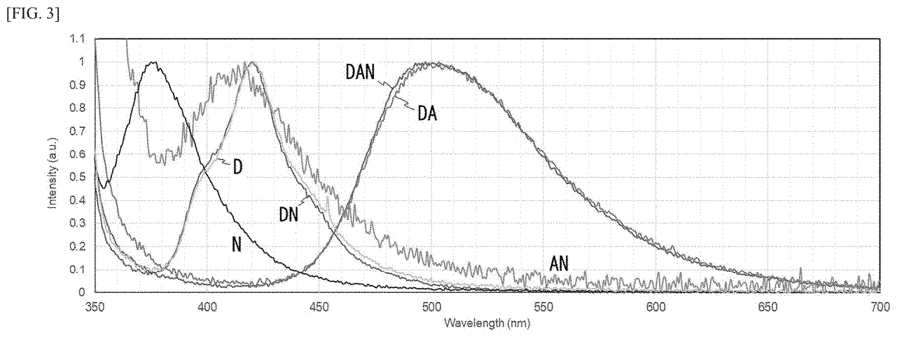

The prepared thin films were irradiated with a light having a wavelength of 300 nm at 300 K, and the resultant emission spectra are shown in FIG. 3. FIG. 3 shows that the donor compound TrisPCz and the acceptor compound SF3-TRZ form an exciplex to emit light, and the emission spectrum from the exciplex does not change by further addition of the adjustment compound PYD2Cz.

The photoluminescence quantum yield (PLQY) was measured, and the thin film DA thereof was 31%, and the thin film DAN thereof was 46%. From this, it is confirmed that the luminous efficiency by the exciplex was greatly improved by further addition of the adjustment compound.

### (Example 2) Thin Film Preparation and Evaluation—2—

Thin films were formed according to the same procedure as in Example 1, except that the ratio by mass of the donor compound TrisPCz, the acceptor compound SF3-TRZ and the adjustment compound PYD2Cz was changed as in the following Table. Also in the same manner as in Example 1, the emission spectra were measured. The emission spectra at 300 to 700 nm were the same as that of the thin film DAN in Example 1. In addition, the transient decay curves were compared, which confirmed that a higher ratio by mass of the adjustment compound PYD2Cz tends to prolong the lifetime of delayed fluorescence. Further, the data of photoluminescence quantum yield (PLQY) were compared, which confirmed that a higher ratio by mass of the adjustment compound PYD2Cz tends to increase the photoluminescence quantum yield.

TABLE 1

| | Composition (% by mass) | | |
|---|---|---|---|
| | Donor | Acceptor | Adjustment |
| | Compound | Compound | Compound |
| Thin Film | TrisPCz | SF3-TRZ | PYD2Cz |
| Thin Film DAN2 | 45 | 45 | 10 |
| Thin Film DAN3 | 25 | 25 | 50 |
| Thin Film DAN4 | 40 | 10 | 50 |

### (Example 3) Thin Film Preparation and Evaluation—3—

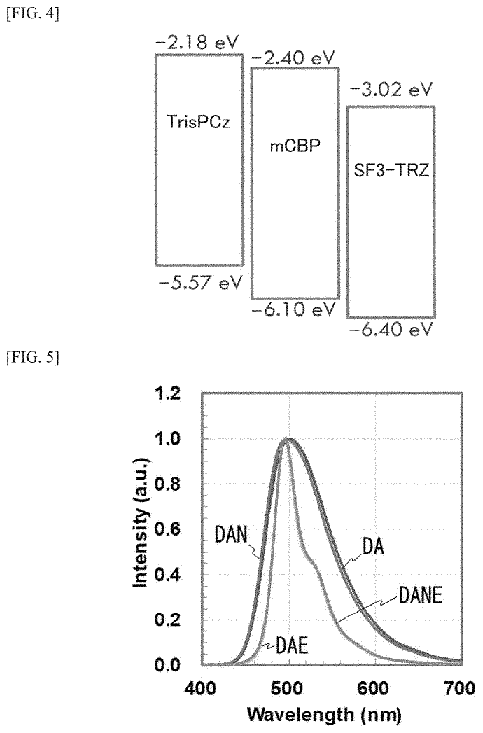

Thin films having a ratio by mass shown in the following Table were formed according to the same procedure as in Example 2, except that mCBP was used as the adjustment compound. The energy level of each compound used in the light emitting layer in Example 3 is shown in FIG. 4. Regarding the thin film using mCBP as the adjustment compound, it was also confirmed that a higher ratio by mass of the adjustment compound tends to prolong the lifetime of delayed fluorescence and tends to increase the photoluminescence quantum yield.

TABLE 2

| | Composition (% by mass) | | |
|---|---|---|---|
| | Donor | Acceptor | Adjustment |
| | Compound | Compound | Compound |
| Thin Film | TrisPCz | SF3-TRZ | mCBP |
| Thin Film DAN5 | 45 | 45 | 10 |
| Thin Film DAN6 | 25 | 25 | 50 |
| Thin Film DAN7 | 40 | 10 | 50 |

### (Example 4) Production and Evaluation of Organic Electroluminescent Device

On a glass substrate having, as formed thereon, an anode of indium tin oxide (ITO) having a thickness of 50 nm, thin films were laminated according to a vacuum evaporation method at a vacuum degree of 10⁻⁵ Pa. First, HAT-CN was formed on ITO to have a thickness of 10 nm, then on this, NPD was formed to have a thickness of 30 nm, and TrisPCz was formed to have a thickness of 10 nm. Next, a donor compound TrisPCz, an acceptor compound SF3-TRZ, and an adjustment compound PYD2Cz were co-evaporated from different evaporation sources at a ratio by mass of 1/1/1 to form a light emitting layer having a thickness of 30 nm. Next, SF3-TRZ was formed to have a thickness of 10 nm, and on this, SF3-TRZ and Liq were formed in a ratio by mass of 7/3 to have a thickness of 30 nm. Further, lithium fluoride (LiF) was vapor-deposited to have a thickness of 2.0 nm, then aluminum (Al) was vapor-deposited to have a thickness of 100 nm to be a cathode. According to the process, an organic electroluminescent device (Device DAN) was produced.

Another organic electroluminescent device (Device DA) was produced according to the same process except that the donor compound TrisPCz and the acceptor compound SF3-TRZ were co-evaporated in a ratio by mass of 1/1 to form a light emitting layer.

Also another organic electroluminescent device (Device DANE) was produced according to the same process except that the donor compound TrisPCz, the acceptor compound SF3-TRZ, the adjustment compound PYD2Cz and a light emitting compound 4DPA-Pyr were co-evaporated from different evaporation sources to form a light emitting layer. At that time, the ratio by mass of the donor compound TrisPCz, the acceptor compound SF3-TRZ, and the adjustment compound PYD2Cz was 1/1/1. The amount of the light emitting compound 4DPA-Pyr was 1% by mass relative to the total amount of the donor compound TrisPCz, the acceptor compound SF3-TRZ, and the adjustment compound PYD2Cz.

Still another organic electroluminescent device (Device DAE) was produced according to the same process except that the donor compound TrisPCz, the acceptor compound SF3-TRZ, and the light emitting compound 4DPA-Pyr were co-evaporated from different evaporation sources to form a light emitting layer. At that time, the ratio by mass of the donor compound TrisPCz, and the acceptor compound SF3-TRZ was 1/1. The amount of the light emitting compound 4DPA-Pyr was 1% by mass relative to the total amount of the donor compound TrisPCz, and the acceptor compound SF3-TRZ.

The emission spectra of the thus-produced four devices are shown in FIG. 5. The emission spectra at 300 to 700 nm of the Device DAN and the Device DA were the same, and the emission spectra at 300 to 700 nm of the Device DANE and the Device DAE were the same. The maximum emission wavelength of the Device DANE and the Device DAE was somewhat a short wavelength than the maximum emission wavelength of the Device DAN and the Device DA. On the other hand, the half width of the Device DANE and the Device DAE was narrower than the half width of the Device DAN and the Device DA.

Regarding the time in which the emission intensity lowered to 95% (LT95), the Device DANE had a longest time. LT95 of the Device DANE was 3.0 times that of the Device DAE, which confirmed that, by adding the adjustment compound, the emission lifetime is exponentially prolonged.

### (Example 5) Solubility Test

A mixture of a donor compound TrisPCz, an acceptor compound SF3-TRZ, and an adjustment compound PYD2Cz was tested for the solubility in 1 ml of toluene. At that time, the mass of the donor compound TrisPCz, the acceptor compound SF3-TRZ, and the adjustment compound PYD2Cz was 4.5 mg, 4.5 mg and 1.0 mg, respectively (Mixture DAN1).

Other solubility tests were carried out according to the same procedure as that for the Mixture DAN1, except that the ratio by mass of the donor compound TrisPCz, the acceptor compound SF3-TRZ, and the adjustment compound PYD2Cz was changed as in the following Table (Mixture DAN2 and Mixture DAN3). All the mixtures were visually confirmed to have dissolved. From this, it is confirmed that the combination of the present invention is applicable to coating-type devices.

TABLE 3

| | Composition (mg) | | |
|---|---|---|---|
| | Donor | Acceptor | Adjustment |
| | Compound | Compound | Compound |
| Mixture | TrtsPCz | SF3-TRZ | mCBP |
| Mixture DAN1 | 4.5 | 4.5 | 1.0 |
| Mixture DAN2 | 2.5 | 2.5 | 5.0 |
| Mixture DAN3 | 4.0 | 1.0 | 5.0 |

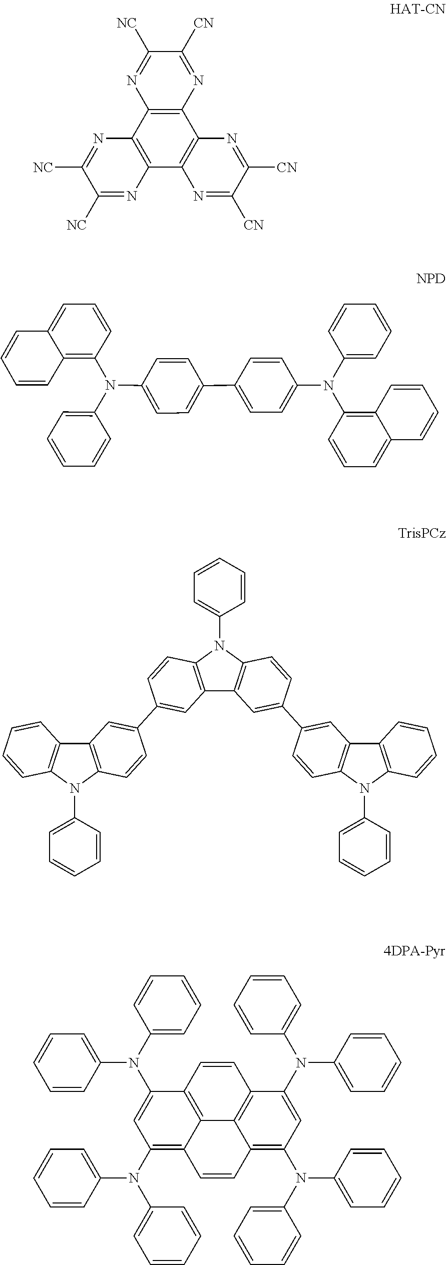 [SMILES: N#Cc1nc2c3nc(C#N)c(C#N)nc3c3nc(C#N)c(C#N)nc3c2nc1C#N ; c1ccc(N(c2ccc(-c3ccc(N(c4ccccc4)c4cccc5ccccc45)cc3)cc2)c2cccc3ccccc23)cc1 ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1ccc(N(c2ccccc2)c2cc(N(c3ccccc3)c3ccccc3)c3ccc4c(N(c5ccccc5)c5ccccc5)cc(N(c5ccccc5)c5ccccc5)c5ccc2c3c54)cc1]

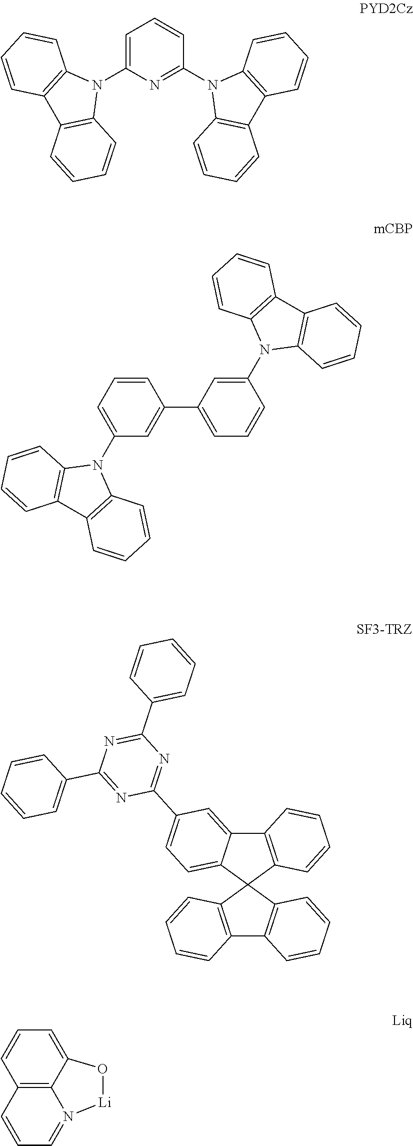

### INDUSTRIAL APPLICABILITY

The light emitting material of the present invention is excellent in at least one of luminous efficiency and emission lifetime. Therefore, the light emitting material of the invention is effectively used as a charge transporting material for organic light emitting diodes such as organic electroluminescent devices. Accordingly, it can be possible to provide an organic light emitting diode that realizes at least one of high luminous efficiency and long emission lifetime. Consequently, the industrial applicability of the present invention is great.

### REFERENCE SIGNS LIST

1 Substrate
2 Anode
3 Hole Injection Layer
4 Hole Transporting Layer
5 Light Emitting Layer
6 Electron Transporting Layer
7 Cathode

1. A light emitting material containing, in addition to a donor compound and an acceptor compound that form an exciplex, an adjustment compound that differs from the donor compound and the acceptor compound, and satisfying a relationship of the following formula (A), formula (B1) and formula (B2):
HOMO(D)>HOMO(N)>HOMO(A) Formula (A)
LUMO(D)>LUMO(N)+0.1 eV Formula(B1)
LUMO(N)>LUMO(A) Formula(B2)
wherein HOMO(D) represents an energy level of HOMO (highest occupied molecular orbital) of the donor compound, HOMO(A) represents an energy level of HOMO of the acceptor compound, HOMO(N) represents an energy level of HOMO of the adjustment compound, LUMO(D) represents an energy level of LUMO (lowest unoccupied molecular orbital) of the donor compound, LUMO(A) represents an energy level of LUMO of the acceptor compound, LUMO(N) represents an energy level of LUMO of the adjustment compound.

2. The light emitting material according to claim 1, further satisfying a relationship of the following formula (C):
HOMO(D)≥HOMO(A)+0.6 eV Formula (C)

3. The light emitting material according to claim 1, further satisfying a relationship of the following formula (D) and formula (E):
T1(D)<T1(N) Formula (D)
T1(A)<T1(N) Formula (E)
wherein T1(D) represents a lowest excited triplet energy level of the donor compound, T1(A) represent a lowest excited triplet energy level of the acceptor compound, and T1(N) represents a lowest excited triplet energy level of the adjustment compound.

4. The light emitting material according to claim 1, wherein the content of the adjustment compound is 30% by mass or more.

5. The light emitting material according to claim 1, wherein the emission intensity from the exciplex is at least 10 times the emission intensity from the adjustment compound.

6. The light emitting material according to claim 1, further containing a light emitting compound.

7. The light emitting material according to claim 6, wherein the emission intensity from the light emitting compound is at least 10 times the emission intensity from the exciplex.

8. The light emitting material according to claim 6, wherein the emission intensity from the light emitting compound is at least 50 times the emission intensity from the adjustment compound.

9. A delayed fluorescent material, containing a light emitting material of claim 1.

10. An organic light emitting diode (OLED), containing a light emitting material of claim 1.

11. An organic light emitting diode (OLED) containing an anode, a cathode, and at least one organic layer that contains a light emitting layer between the anode and the cathode, wherein:
the light emitting layer contains a light emitting material of claim 1.

12. An organic light emitting diode (OLED) containing an anode, a cathode, and at least one organic layer that contains a light emitting layer between the anode and the cathode, wherein:
the light emitting layer contains a light emitting material of claim 6.

13. A screen or a display, containing a light emitting material of claim 1.

14. A method for producing an OLED display, the method comprising:
forming a barrier layer on a base material of a mother panel,
forming plural display units on the barrier layer each on a cell panel basis,
forming an encapsulation layer on each display unit of the cell panel, and
forming an organic film by coating on the interface portion between the cell panels, wherein:
the organic film contains a light emitting material of claim 1.
